(19) United States
(12) Patent Application Publication
(10) Pub. No.: US 2026/0215270 A1
(43) Pub. Date: Jul. 23, 2026

(54) Methods for fluid cooling semiconductor devices

(71) Applicant: Adeia Semiconductor Bonding Technologies Inc., San Jose, CA (US)

(72) Inventors: Cyprian Emeka Uzoh, San Jose, CA (US); Rajesh Katkar, Milpitas, CA (US); Belgacem Haba, Saratoga, CA (US)

(21) Appl. No.: 19/425,277

(22) Filed: Dec. 18, 2025

Related U.S. Application Data
(62) Division of application No. 18/084,232, filed on Dec. 19, 2022.

(51) Int. Cl. H10W 40/47; H10W 90/00

(52) U.S. Cl. CPC H10W 40/47; H10W 90/00

(57) ABSTRACT

Methods are disclosed herein for fluid cooling semiconductor devices. A method comprises forming a thermal exchanger on the semiconductor device by etching cavities in the semiconductor device, depositing a thermally conductive layer in the cavities, and forming, from the thermally conductive layer, the thermal exchanger comprising (i) thermal vias disposed in the cavities and (ii) an upper portion of the thermally conductive layer to form protrusions above the first side. The method further comprises coupling a housing to the thermal exchanger to form a fluid chamber having a chamber volume disposed between the thermal exchanger and the housing, where the upper portion of the thermal exchanger is exposed to and faces the chamber volume.

### CROSS REFERENCE TO RELATED APPLICATION

This application is a continuation of U.S. patent application Ser. No. 18/084,232, filed Dec. 19, 2022, the disclosure of which is hereby incorporated by reference herein in its entirety.

### FIELD

The present disclosure relates to advanced packaging for microelectronic devices, in particular, around thermally conductive structures for fluid cooling high-power devices and methods of manufacturing the same.

### BACKGROUND

The future of large-scale computing includes many challenges to be overcome. One critical challenge is efficient thermal dissipation as improved device (or chip) performance demands higher power density due to, e.g., increased gate density, increased number of cores in multi-core processors, etc. The higher power density results in increased thermal flux and higher operating temperatures, which limit and/or degrade the device's performance, efficiency, and reliability. Conventionally, a fluid cooling system includes a heat dissipation component (e.g., thermal spreader or heat sink) and a fluid cooling component (e.g., liquid pipe or circulation chamber).

A surface of a microelectronic device or package is typically coupled to the heat dissipation component indirectly at a thermal interface (e.g., using a thermal paste or other thermal interface material (TIM)). The other end of the heat dissipation component may be thermally coupled to a fluid chamber of the fluid cooling component using a second TIM layer, where the fluid coolant is circulated through the fluid chamber. Some example fluid coolants include deionized water, deoxygenated water, and water containing small amount of water-soluble lubricant or mix of such lubricants. The overall concentration of the water-soluble lubricant may be up to about 5% (e.g., concentration of 1%) and preferably less than 0.1% in some implementations. The thermal conduction pathway, or thermal path, between the device's surface and the fluid coolant includes multiple interfaces, resulting in a combined thermal resistance that inhibits the heat transfer and dissipation, limiting the cooling efficiency. In addition, a conventional fluid cooling system conducts just the surface thermal energy away from the device. Internal thermal energy within the device must first reach the surface at the thermal interface before being dissipated, which may further reduce the cooling efficiency in high-powered devices, in particular, devices comprising three-dimensional stacked integrated circuits.

Accordingly, there is a need for improved thermally conductive structures to dissipate heat in conjunction with fluid cooling.

### SUMMARY

To address the above-identified needs, the present disclosure provides herein thermally conductive structures designed for fluid cooling that extend into a semiconductor device, along with methods of manufacturing such structures. A thermally conductive structure in the present disclosure may be referred to, for example, as a thermal via structure, an integrated thermal exchanger, and/or a thermal exchanger. Such thermally conductive structures may be implemented in a microelectronic assembly and/or package, for example, to facilitate cooling of high-powered devices. The semiconductor device may comprise a semiconductor wafer or substrate and integrated circuitry. In some embodiments, the semiconductor device may comprise a dielectric layer and/or a back-end-of-line (BEOL) layer disposed over opposing sides of the device. For example, the BEOL layer may be a bonding layer for hybrid bonding to a substrate including a BEOL structure. An integrated thermal exchanger may be disposed over the device as follows.

The integrated thermal exchanger starts from above a device and includes a portion extending into the device, stopping before reaching the opposite side. The portion of the thermal exchanger extending into the device conducts heat inside the device to a top portion of the thermal exchanger. A housing may be coupled to the thermal exchanger to form a fluid chamber. For example, the housing may include walls that define a chamber volume of the fluid chamber, where the walls prevent coolant leakage. For example, the housing may be attached or bonded to a side of the thermal exchanger or to another part of the device such that fluid coolant cannot leak out of the fluid chamber through the walls. In some embodiments, the housing may define a fluid-cooling chamber such that a portion of the thermal exchanger is exposed to the chamber volume. The portion of the thermal exchanger may be exposed such that the exposed portion contacts a suitable heat-transfer fluid or fluid coolant in the chamber volume to enable thermal cooling of the device. Fluid coolant may include gaseous and/or liquid coolants. The thermal exchanger thus provides a thermal interface for the device with fluid coolant flowing through and circulating within the fluid chamber. A protective layer may be disposed over at least the exposed portion of the thermal exchanger and/or devices in the chamber volume to protect against damage (e.g., corrosion, oxidation, etc.) and/or contamination due to contact with the fluid coolant.

For example, the portion of the thermal exchanger extending into the device may be a plurality of thermally conductive vias. These thermally conductive vias may be referred to as thermal vias, extended thermal vias and/or blind thermal vias. The thermal vias start from first ends located at a level above the device's side to second ends inside the device. The second ends stop at a second level before reaching the opposite side (e.g., before the front side of the device). The first ends of the thermal vias may be shaped such that heat is efficiently transferred to fluid coolant. For example, the first ends may be sharp-edged (e.g., rectangular, rhomboid), roughened, and/or curved (e.g., oblong, hemispherical) to disturb flow of the fluid coolant proximate to the first ends.

In another non-limiting example, the thermal exchanger may include a thermally conductive layer that is conformally disposed over the device's side and inside one or more blind cavities extending into the device. As described herein, a blind cavity is a cavity in a structure (e.g., substrate, wafer, device, etc.) that starts at a first side and stops before reaching a second side opposite to the first side, defining the cavity height. The conformally disposed layer may cover the sides of the blind cavities to enable heat transfer without exposing the device to fluid coolant. Fluid coolant can flow inside the blind cavities and remove heat collected by the conformally disposed layer. The sides of the blind cavities may be roughened to improve heat exchange between the conformally disposed layer and the fluid coolant.

The thermal exchanger can be patterned and/or shaped to improve heat transfer efficiency to the fluid coolant. For example, the housing and thermal exchanger may be configured such that a fluid coolant flows in contact with a top side of the thermal exchanger. The top portion can include a topography that increases turbulence in the fluid coolant near the top side (e.g., by plating metal rows on the top side that protrude into the fluid coolant). The increased turbulence may improve heat transfer efficiency from the thermal exchanger to the fluid coolant.

Such thermally conductive structures and implementations thereof allow for a shorter, more efficient thermal path than conventional fluid cooling systems. The combined thermal resistance of the thermal path between a device and fluid coolant is reduced by replacing the various thermal interfaces in a typical cooling system with a thermal exchanger having a high thermal conduction. The thermal exchanger may be further shaped and/or patterned to improve cooling efficiency. Further, heat may be readily extracted from microelectronic devices since the thermal exchanger includes a portion (e.g., thermal vias) that reaches heat-generating regions within the microelectronic device.

The fluid chamber may be formed by coupling the housing to the thermal exchanger such that the fluid chamber is shaped to enhance the cooling efficiency. For example, a housing may be attached to the top side of the thermal exchanger by using adhesive, a bonding layer, and/or other bonding techniques, where the bonding layer forms a hermetic seal at the interface between the thermal exchanger and the housing. The housing may be coupled to at least one fluid inlet and at least one fluid outlet. The fluid inlet and fluid outlet may be configured to circulate fluid coolant through the fluid chamber such that the fluid coolant contacts the thermal exchanger exposed to the chamber volume, removing thermal energy from the device and cooling the device via the thermal exchanger. The shape of the housing walls can be rectangular. For example, the walls of the housing may be joined at right angles to form a box-like shape. In some embodiments, to enhance cooling efficiency, the walls of the housing may be configured to suppress entrapment of air pockets or bubbles in the fluid chamber, for example, by modifying the shape of the housing. The modified shape can adjust (e.g., increase or decrease) turbulence in flow of the fluid coolant proximate to the inner wall surfaces of the housing, which encourages laminar flow and helps suppress air bubble entrapment. For example, the walls of the housing can be joined at obtuse angles. In another, non-limiting example, the shape of the housing may be arched or curved. In some embodiments, the thermal exchanger and one or more devices may be exposed to the chamber volume of the fluid chamber. For example, a device and a chip stack may be bonded to the same substrate, where a thermal exchanger is disposed over the device. The housing may be configured such that the device, the thermal exchanger, and the chip stack are exposed to the chamber volume. Such a configuration may allow fluid coolant to cool all the structures in the same fluid chamber.

The integrated thermal exchanger may comprise one or more thermally conductive materials having a higher thermal conductivity than copper to enhance heat transfer. Some exemplary materials include diamond or carbon nanotubes. A heterogeneous integrated thermal exchanger comprising multiple thermally conductive materials may be referred to as a heterogeneous exchanger. For example, a heterogenous exchanger may have a top portion comprising primarily diamond (e.g., a diamond-based layer or die hybrid bonded to the device) and a metal-based portion extending into the device. The heterogeneous exchanger may have an improved heat transfer by having a more thermally conductive material than copper in contact with the fluid coolant, improving the cooling efficiency of the overall structure.

It should be noted that the structures and/or methods of manufacturing thereof described herein may be applied to, combined with, or used in conjunction with, other structures, methods, and/or apparatuses.

### BRIEF DESCRIPTION OF THE DRAWINGS

The above and other objects and advantages of the disclosure will be apparent upon consideration of the following detailed description, taken in conjunction with the accompanying drawings, in which:

FIG. 1 shows a schematic side view of a fluid-cooled microelectronic assembly having an integrated thermal exchanger, according to one embodiment;

FIG. 2 shows schematic side views of exemplary thermally conductive structures extending into a device or substrate, in accordance with some embodiments of the disclosure;

FIG. 3 shows schematic side views of exemplary devices including a heterogeneous integrated thermal exchanger, in accordance with some embodiments of the disclosure;

FIG. 4 shows schematic side views of exemplary devices having shaped thermal vias, in accordance with some embodiments of the disclosure;

FIG. 5 shows schematic side views of exemplary microelectronic assemblies including a thermal exchanger disposed in a fluid chamber, in accordance with some embodiments of the disclosure;

FIG. 6 shows a schematic side-view of an exemplary microelectronic assembly including a thermal exchanger and a device stack disposed in a fluid chamber, in accordance with some embodiments of the disclosure;

FIG. 7 shows schematic side views of exemplary microelectronic stacks including a grounded thermal exchanger, in accordance with some embodiments of the disclosure;

FIG. 8 shows schematic side views of exemplary devices including a conformal thermal exchanger within a wide cavity, in accordance with some embodiments of the disclosure;

FIG. 9 shows schematic side views of an exemplary microelectronic assembly including a roughened, conformal thermal exchanger, in accordance with some embodiments of the disclosure;

FIGS. 10A-10B (collectively FIG. 10) show schematic side views outlining an exemplary process for forming a thermal exchanger, in accordance with some embodiments of the disclosure;

FIG. 11 shows schematic side views of exemplary structures when forming a conformal and/or shaped thermal exchanger, in accordance with some embodiments of the disclosure;

FIG. 12 shows schematic side views outlining an exemplary process for forming a thermal exchanger with upper portions that extend into a fluid chamber, in accordance with some embodiments of the disclosure;

FIG. 13 is a flowchart of a process for forming and assembling a thermal exchanger for fluid cooling, in accordance with some embodiments of the disclosure;

FIG. 14 is a flowchart of a process for forming a thermal exchanger including extended thermal vias for fluid cooling, in accordance with some embodiments of the disclosure;

FIG. 15 is a flowchart of a process for forming a conformal, shaped thermal exchanger for fluid cooling, in accordance with some embodiments of the disclosure;

FIG. 16 is a flowchart of a process for forming a conformal, shaped thermal exchanger within a large cavity for fluid cooling, in accordance with some embodiments of the disclosure;

FIG. 17 is a flowchart of a process for forming a fluid cooling module including a conformal thermal exchanger within patterned and/or textured cavities, in accordance with some embodiments of the disclosure; and

FIG. 18 is a flowchart of a process for forming a thermal exchanger including extended thermal vias for fluid cooling, in accordance with some embodiments of the disclosure.

The figures herein depict various embodiments of the invention for purposes of illustration only. It will be appreciated that additional or alternative structures, assemblies, systems, and methods may be implemented within the principles set out by the present disclosure.

### DETAILED DESCRIPTION

In the following paragraphs, cross-sections of exemplary structures are described herein for illustrative purposes. It is noted and appreciated that the present disclosure includes three-dimensional microelectronic structures and other microelectronic architectures having the described features along with implementations and processes for manufacturing such structures.

As used herein, the term “substrate” means and includes any workpiece, wafer, or article that provides a base material or supporting surface from which or upon which components, elements, devices, assemblies, modules, systems, or features of the heat-generating devices, packaging components, and microelectronic assembly components described herein may be formed. For example, a substrate may be a wafer with integrated or embedded circuitry or a semiconductor-on-insulator (SOI) substrate. The term substrate also includes “semiconductor substrates” that provide a supporting material upon which elements of a semiconductor device are fabricated or attached, and any material layers, features, and/or electronic devices formed thereon, therein, or therethrough. The term “substrate” may be used interchangeably with the term “wafer” herein. A non-exhaustive list of semiconductor materials includes silicon (Si), gallium arsenide (GaAs), polymeric, ceramic, carbon-based substrates such as diamond, silicon carbide (SiC), germanium (Ge), Si₁₋ₓGeₓ, etc.

As used herein, the term “circuitry” means and includes any electrical circuit(s) or system(s) with active and/or passive electronic components, conductive wires or traces, semiconductor-based devices, etc. A die can refer to any suitable integrated device die. Some non-limiting examples include a processor die, controller die, memory die, microelectromechanical (MEMS) systems die, optical device, etc. Circuitry may be patterned on a surface or within a suitable part of the die.

The semiconductor devices described herein generally have a “front side” or “device side,” e.g., the side on which semiconductor device elements are fabricated, such as transistors, resistors, and capacitors, and a “back side” that is opposite the device side. The term “active side” should be understood to include a surface of the device side of the substrate and may include the device side surface of the substrate and/or a surface of any material layer, device element, or feature formed thereon or extending outwardly therefrom, and/or any openings formed therein. Thus, for example, a front side may be referred to as a front surface. It should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” are also used to describe surfaces of material layers or features formed on, in, or through the substrate, whether or not the material layers or features are ultimately present in the fabricated or assembled device.

As described herein, a substrate may refer to a stack of substrates, each comprising a unitary bulk material. Each of the plurality of substrates may have substantially the same size and shape when viewed from top-down (in the Z-direction) so that the interfacing surfaces are substantially coextensive with one another. For example, each substrate in a stack may have a thickness (in the Z-direction) of between about 0.5 mm and about 10 mm, or between about 1 mm and about 8 mm, or between about 1 mm and 6 mm, such as about 0.5 mm or more, such as about 1 mm or more, or about 2 mm or more, or about 10 mm or less, such as about 8 mm or less, or about 6 mm or less.

It should be noted that the substrates described herein are not limited to crystalline silicon or other semiconductor material. It is contemplated that substrates may be formed from a bulk substrate material comprising metal, metal alloys, ceramics, composite materials or other low thermal-expansion-coefficient (CTE) materials suitable for bonding using the methods described herein. Some example materials include but are not limited to copper, aluminum, copper alloys (e.g., copper molybdenum alloys and copper tungsten alloys), iron cobalt nickel alloys (e.g., Kovar® from Magellan Industrial Trading Co., Inc. of South Norwalk Connecticut USA), iron cobalt nickel silver alloys, iron nickel alloys (e.g., Invar® superalloys from Magellan), iron nickel silicon alloys, aluminum silicon carbides, aluminum silicon alloys, beryllium, beryllium oxides, beryllium and beryllium oxide composites, aluminum-graphite fibers, copper-graphite fibers, metal diamond composite materials (e.g., aluminum diamond composites and silver-diamond composites), metal oxides, metal nitrides, and combinations thereof. The non-crystalline silicon substrate materials may be prepared for bonding as described herein and may or may not include a dielectric material layer deposited on a bonding surface.

Spatially relative terms are used herein to describe the relationships between elements, such as the relationships between substrates, heat-generating devices, thermal exchange components, device packaging components, and other features. Unless the relationship is otherwise defined, terms such as “above,” “over,” “upper,” “upwardly,” “outwardly,” “on,” “below,” “under,” “beneath,” “lower,” and the like are generally made with reference to the X, Y, and Z directions set forth in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

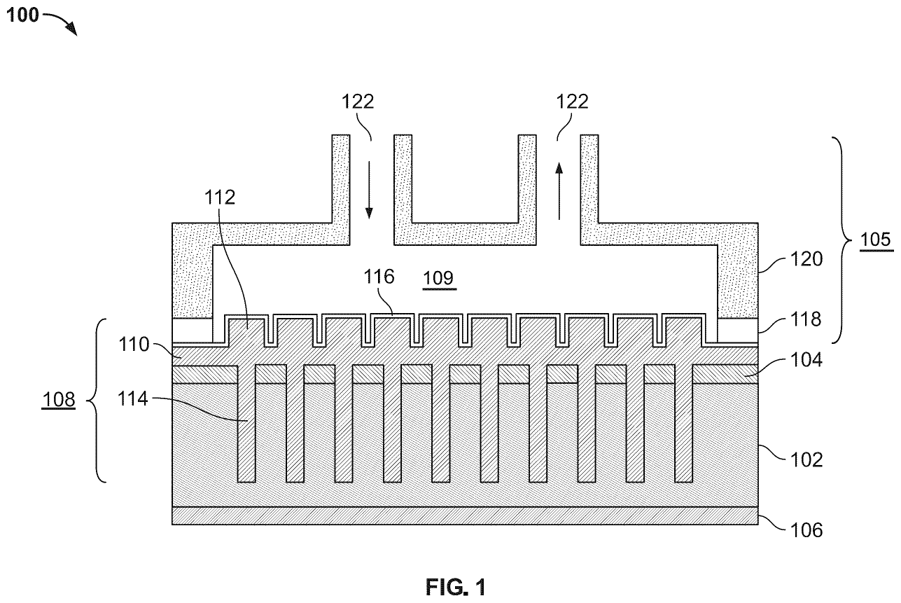

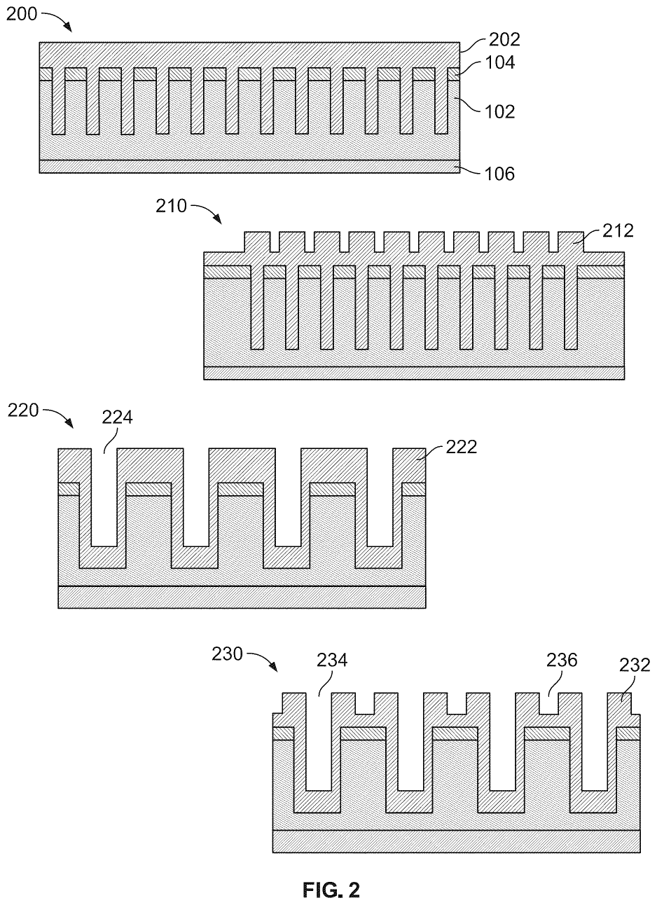

FIG. 1 is a schematic side-view of a fluid-cooled microelectronic assembly 100, according to one embodiment. Here, the assembly 100 includes a semiconductor device 102 and an integrated fluid chamber 105. The device 102 generally includes a front (active side) comprising device components, such as transistors, capacitors, resistors, and/or memory cells and one or more back end of line layers (BEOL) 106, e.g., dielectric layers and interconnecting wires, vias, and contacts (i/o pads) formed therein or thereon, and a second side, herein a “back-side” disposed opposite the front side. The device 102 may include a singulated device (as shown) or a stack of devices. In some embodiments, the device 102 comprises a dielectric material layer 104 disposed on the back side of the device 102.

As shown, the fluid chamber 105 (disposed on the back side of the device or a back side of the uppermost device in a stack) includes a thermal exchanger 108 formed on or bonded to the device 102 and a housing 120 coupled to the thermal exchanger 108 to collectively define a chamber volume 109 therebetween. Coolant may flow into and out of the chamber volume 109 through inlet/outlet openings 122 formed through an upper portion of the housing 120. Here, the thermal exchanger 108 includes a thermally conductive (TC) material layer 110 and a corrosion-resistant protective layer 116 disposed on the TC material layer 110.

To enhance thermal transfer, the TC material layer 110 may have a higher thermal conductivity than the substrate, e.g., such as a crystalline silicon wafer, used to form the device 102. For example, the TC material layer 110 may be formed from a material comprising copper (Cu), silver (Ag), gold (Au), aluminum nitride (AlN), silicon carbide, tungsten, graphite, diamond, metal-diamond composite, diamond-like carbon, carbon nanotubes, or examples thereof. In some embodiments, a substrate used to form the device 102 may comprise silicon having a thermal conductivity of about 148 W/mK and the TC material layer 110 may comprise copper or a copper-based alloy having a thermal conductivity of about 385 W/mK or greater. In other embodiments, the TC material layer 110 may comprise diamond or a metal-diamond composite having a higher thermal conductivity of about 2200 W/mK or greater. In some embodiments, the TC material layer 110 has a thermal conductivity that is 2× or more than the thermal conductivity of the bulk substrate material used to form the device 102, such as 3× or more, 5× or more, or, for example, 10× or more.

In some general aspects, the TC material layer 110 includes an upper portion comprising a patterned side 112 and a lower portion comprising a plurality of thermal vias 114. In some embodiments, the patterned side 112 may comprise a patterned surface. The patterned side 112 may include a plurality of protrusions that project upwardly into the chamber volume 109 to increase overall contact duration and enhance heat transfer between the TC material layer 110 and a coolant fluid by disrupting laminar flow of the coolant thereover. For example, the patterned side 112 may include one or more protuberances (e.g., bumps, hills, mounds, etc.) that provide for increased turbulence of the coolant fluid at an interface of the fluid and the thermal exchanger 108 when compared to a thermal exchanger having an unpatterned side. The increased turbulence provides increased convective heat transfer between the thermal exchanger 108 and the coolant fluid and thus provides improved cooling efficiency. In another non-limiting example, the patterned side 112 may include protrusions arranged in a staggered pattern (when viewed from the Z-direction) to define a plurality of non-linear fluid channels. Some side or surface patterns are described herein for illustrative purposes; however, it is contemplated that other side or surface patterns would be suitable for implementations within the teachings of the present disclosure.

The thermal vias 114 extend through dielectric layer 104 and into the device 102, starting at a first level above dielectric layer 104 and ending at a second level between the front side and back side of the device 102. For example, the thermal vias 114 may fill blind openings formed in the back side device 102. In some embodiments, a diffusion barrier layer (not shown) is disposed between thermal vias 114 and the walls of the openings to prevent material of the thermal vias from diffusing into the device 102. Some non-limiting examples of material that may be used for the diffusion barrier layer include titanium, tantalum, titanium nitride, tantalum nitride, and combinations thereof.

The thermal vias 114 may be of various dimensions (height, width, etc.) and shapes (cylindrical, rectangular, conical, frustoconical, ovoid, oblong, etc.). For example, the thermal vias 114 may have widths of about 0.1 to 300 microns, depending on the dimensions of the device 102 and/or may be a high-density array with a pitch of about 1 to 20 microns. In some embodiments, the thermal vias 114 may vary in size and shape across the back side of the device 102. For example, some of the inner thermal vias may be wider than vias at the periphery of the device 102 or vice versa. In some embodiments, at least some of the thermal vias 114 are disposed over device elements that generate a high amount of heat relative to other components of the device, commonly referred to as device hot spots. For example, an integrated circuit die may be disposed at a hot spot of the device. Some of the thermal vias 114 may extend toward a hot spot of the device, stopping at a level before reaching the hot spot to conduct heat away from the die to the patterned side 112. In some embodiments, the ends of the thermal vias 114 at the second level may be about 3 microns to 20 microns away from heat-generating components near or on the second side of the device 102. By positioning the ends of the thermal vias 114 proximate to the heat-generating elements but spaced apart therefrom by a portion of the substrate, the thermal vias 114 can remove heat from the hot-spot regions without inducing mechanical stress fields (e.g., from the thermal vias 114) in the device 102 and degrading the performance thereof. In some embodiments, the thermal vias 114 may extend a distance of about 80% to 95% of a thickness of the device 102. For example, for a device 102 having a total thickness of about 100 microns and BEOL layer thickness of about five microns, the thermal vias 114 may be about 90 microns deep (i.e., around five microns from the active device region) to facilitate heat transfer from the device elements. In some embodiments, the thermal vias 114, may penetrate localized heat-generating pockets of the device 102.

Beneficially, the thermal vias 114 provide for increased cooling efficiency by reducing the thermal resistance of the heat dissipation path from heat-generating components formed on the front side of the device 102 to coolants flowed through the chamber volume 109. For example, by replacing portions of the substrate used to form the device 102, e.g., by forming openings in the crystalline silicon substrate and depositing the TC material layer 110 thereover and therein, the thermal vias 114 provide for improved thermal conductivity when compared to a crystalline silicon substrate formed without the thermal vias 114. Table 1 illustrates improvements in thermal conductivity by adding copper or diamond thermal vias 114 to a crystalline silicon substrate as compared to the substrate without the vias, where the % Cu or diamond corresponds to the volume of silicon removed when forming the openings.

TABLE 1

| | Relative improved |
|---|---|
| TC Material | thermal conductivity (%) |
| 85% Si, 15% Cu | 24 |
| 70% Si, 30% Cu | 48 |
| 50% Si, 50% Cu | 80 |
| 99% Si, 1% Diamond | 14 |
| 95% Si, 5% Diamond | 69 |
| 90% Si, 10% Diamond | 139 |
| 85% Si, 15% Diamond | 208 |
| 70% Si, 30% Diamond | 461 |
| 50% Si, 50% Diamond | 693 |

In some embodiments, the patterned side 112 is covered by a protective layer 116 that prevents corrosion, oxidation, and/or other damage to the TC material layer 110 from coolant fluids flowing into and out of the fluid chamber 109. In some embodiments, the protective layer 116 is chosen from a suitable material and thickness to decrease interference in the thermal path between thermally conductive structure 108 and fluid coolant. Generally, the protective layer 116 is a relatively thin conformal anti-corrosive coating comprising an electrically insulating and/or thermally conductive material. In some embodiments, the protective layer 116 has a thickness in the range of about 10 nm to about 200 nm. In some embodiments, the protective layer 116 may have a thickness greater than about 200 nm.

Some exemplary conductive materials for the protective layer 116 include metal alloys such as nitrogen-based alloys, titanium-based alloys, nickel-based alloys, cobalt-based alloys, vanadium-based alloys, tungsten-based alloys, and combinations thereof. For example, a conductive protective layer may consist of a thin layer comprising a titanium alloy, nickel alloy, cobalt alloy, vanadium alloy, tungsten alloy, or a combination thereof, where the alloy may, in some embodiments, comprise nitrogen. Some exemplary non-conductive materials include silicon-based nitrides (SₓN_{y}), silicon-based carbides (SiₓC_{y}), silicon-based oxynitrides (SiOₓN_{y}), silicon-based carbonitrides (SiCₓO_{y}N_{z}), and other suitable silicon-based variants thereof. For example, the protective layer 116 may comprise corrosion-resistant stoichiometric or non-stoichiometric dielectric material such as silicon bearing nitrides (SₓN_{y}) and/or carbonitrides (SiCₓO_{y}N_{z}).

The microelectronic assembly 100 includes a fluid chamber 105 with an adhesive such as bond layer 118, the housing 120, and the fluid pipes 122. The housing 120 and/or other components of fluid chamber 105 may be formed separately and later assembled to form the fluid chamber 105 as part of the microelectronic assembly 100. The housing 120 may be bonded to the thermal exchanger 108, substrate 102, or a second substrate via the bond layer 118. The bond layer 118 may be formed using any suitable technique such that a hermetic seal is formed at the interface of the housing 120, for example, between the thermal exchanger 108 and the housing 120. For example, the bond layer 118 may comprise a suitable non-porous adhesive that is resistant or immune to the fluid coolant. In another example, the bond layer 118 may comprise a hybrid bond between the housing 120 and a bonding surface of the microelectronic stack (e.g., via an intervening bonding layer). In a third non-limiting example, the bond layer 118 may comprise a mechanical seal including interlocking features in combination with any other suitable technique. The hermetic seal formed via bond layer 118 prevents fluid coolant from leaking out of the fluid chamber 105 at the joint.

The fluid chamber 105 may enclose a portion of the thermal exchanger 108 or a microelectronic stack including the device 102 and the thermal exchanger 108. The thermal exchanger 108 may cover more than a top side over the device 102. For example, the thermal exchanger 108 may include a patterned layer extending out from layer 110 over at least portions of outer sides of the device 102 in embodiments where the entire microelectronic stack is in chamber volume 109. In some embodiments as shown in FIG. 1, the fluid chamber encloses a top portion of the thermal exchanger 108. The top portion transfers the heat conducted away from the device to the fluid coolant inside the fluid chamber. For example, as shown in FIG. 1, the fluid chamber encloses the patterned side 112 via the housing 120. The housing 120 may comprise a coolant-proof material. For example, the housing 120 may comprise a non-porous polymer. In some embodiments, sides of the housing 120 are coated to isolate the housing from the fluid coolant inside the fluid chamber and/or prevent warpage. Some exemplary materials for the coating of the housing 120 include a nickel-based alloy such as nickel-tungsten (NiW) and/or cobalt-nickel (CoNi). Although not shown in FIG. 1, at least one rigid bar or stiffener may be embedded inside or attached outside the housing of the fluid chamber for structural support (e.g., to compensate for fluid pressure within the fluid chamber). Fluid pipes 122 allow fluid coolant to flow through the fluid chamber. Fluid pipes 122 may be coupled to an external thermal interface or other cooling system. For example, fluid pipes 122 may conduct the coolant to an external heat sink. While one inlet and one outlet are shown as fluid pipes 122 in FIG. 1, any suitable configuration of fluid pipes may be used that includes at least one inlet and at least one outlet to allow for coolant flow.

The microelectronic assembly 100 is not limited to the aforementioned components. While FIGS. 1-12 may depict similar components, other suitable components or combinations thereof may be added and/or substituted without departing from the teachings in the present disclosure. Each of the aforementioned components may be modified, replaced, and/or combined as further detailed with respect to FIGS. 2-12.

It should be noted that the structural features described herein (cavities, protrusions, patterned sides, etc.) are shown as having substantially vertical orientations, which may result from an isotropic etch process. It is contemplated that these structural features may also be formed using an anisotropic etch process, for example, such that the sides of the structures may be sloped with respect to the substrate surface and/or suitably shaped depending on the implementation. It is contemplated that the structural features from a top view may be in various shapes such as circles, ellipses, rectangles, etc.

In some embodiments, the thermal exchanger is patterned using a combination of lithography and/or etch processes. For example, patterning a side (or surface) includes patterning a mask layer using a lithography process and removing material from the side by exposing the side to a chemically reactive etchant through openings in the mask layers. In some embodiments, the sides may be patterned using a micro-abrasion process where micro-abrasive particles are directed through openings formed in a mask template or mask layer disposed thereover or thereon. The structures described herein may be modified using any suitable method including machining, casting, forging, molding, or the like.

Generally, direct bonding includes preparing the bonding surfaces, aligning, and contacting the bonding surfaces. Preparing the surfaces may include smoothing the respective surfaces to a desired surface roughness, such as between 0.1 to 3.0 nm RMS, activating the surfaces to weaken or open chemical bonds in the dielectric material, and terminating the surfaces with a desired species. Smoothing the surfaces may include polishing the substrates using a chemical mechanical polishing (CMP) process. Activating and terminating the surfaces with a desired species may include exposing the surfaces to radical species formed in a plasma.

In some embodiments, the plasma is formed using a nitrogen-containing gas, e.g., N₂, and the terminating species includes nitrogen and hydrogen. In some embodiments, the surfaces may be activated using a wet cleaning process, e.g., by exposing the surfaces to an aqueous ammonia solution. In some embodiments, the dielectric bonds may be formed using a dielectric material layer deposited on one or on both of the surfaces to be bonded. Direct dielectric bonds may be formed by contacting the deposited dielectric material layer of one substrate directly with a bulk material surface of the other substrate, e.g., a bulk semiconductor or poly-silicon material surface. In such embodiments, the bulk material surface may comprise a thin layer of native oxide or may be cleaned prior to contact so that it is substantially free of native oxide.

Directly forming direct dielectric bonds between substrates may include bringing the prepared and aligned surfaces into direct contact at a temperature less than 150° C., such as less than 100° C., for example, less than 30° C., or about room temperature, e.g., between 20° C. and 30° C. Without intending to be bound by theory, it is believed that the hydrogen terminating species diffuse from the interfacial bonding surfaces and chemical bonds are formed between the remaining nitrogen species during the direct bonding process. In some embodiments, the direct bond is strengthened using an anneal process, where the substrates are heated to and maintained at a temperature of greater than about 30° C. and less than about 450° C., for example, greater than about 50° C. and less than about 250° C., or about 150° C. for a duration of about 5 minutes or more, such as about 600 minutes or longer in some implementations. In some general aspects, a higher bonding temperature may result in shorter annealing times and vice versa. For example, if the bonding surface comprises of sapphire, the post activation bond energy is sufficiently strong that further higher annealing may not be necessary. In some aspects, the bonds will strengthen over time even without the application of heat. Thus in some embodiments, the method does not include heating the substrates.

When substrates and the like are bonded using hybrid dielectric and metal bonds, the method may further include planarizing or recessing metal features below the field surface before contacting and bonding the dielectric material layers. After the dielectric bonds are formed, the substrates may be heated to a temperature of 150° C. or more for a period of about 1 hour or more, such as between 8 and 24 hours, to form direct metallurgical bonds between the metal features. Suitable direct dielectric and hybrid bonding technologies that may be used to perform aspects of the methods described herein include ZiBond®, DBI®, or DBI® Ultra, each of which are commercially available from Adeia Holding Corp., San Jose, CA, USA.

FIG. 2 shows schematic side views of exemplary thermally conductive structures extending into a device or substrate, in accordance with some embodiments of the disclosure. Structure 200 includes a thermal exchanger with thermal vias extending into the device 102 and a substantially smooth portion 202 designed to interact with fluid coolant. The structure 210 may include a thermal exchanger with features similar to the thermal exchanger 108. Patterned side 212 may include a different pattern of protrusions than the patterned side 112. For example, the patterned side 212 may include metal rows across the surface of the thermally conductive structure. In another example, the patterned side 212 may include shaped metal bumps or rods extending away from the side, configured to substantively disturb the flow of the fluid coolant. In some embodiments, one or more fluid-cooling cavities are formed inside portions of the structures 202, 212 that extend into the cavities in the device 102. For example, the fluid-cooling cavity inside a thermal via allows coolant to reach the well or bottom of the thermal via. The fluid-cooling cavity provides additional surface area for interaction with fluid coolant and may improve the cooling efficiency.

In some embodiments, the thermal exchanger is a conformal structure disposed over the substrate and coating walls of the cavities in the substrate rather than protruding out of the cavities. As shown in FIG. 2, the structures 220 and 230 include respective conformal thermally conductive structures 222 and 232. Structure 222 includes the openings 224 for fluid coolant to flow over a larger portion of the structure 222 that is inside the device 102. Structure 232 includes the deep openings 234 and shallow openings 236. Shallow openings 236 may be formed, for example, by etching the structure 222. Shallow openings 236 may be formed, for example, by at least partially etching the underlying substrate before disposing the conformal structure 232. In some advantageous aspects, a cooling structure (e.g., the structures 220 and 230) with inside cavities (such as cavities defined by the openings 224, 234 and/or 236) may have reduced warpage or stresses on the surroundings than a structure comprising a thermal structure without inside cavities (e.g., the structure 202). While one opening is shown between the deep openings 234 at the top side of the structure 232, multiple shallow openings may be formed and are not limited to the top side. For example, the structure 232 may include two or more shallow openings between the deep openings 234. Additionally, or alternatively, the shallow openings 236 may be placed at the bottom portions of the structure 232 inside the deep openings 234. For example, portions of the structure 232 that are inside the deep openings 234 may be etched to form the shallow openings 236 along sidewalls of the structure 232 inside the cavities. By flowing inside the openings 224, 234, and 236, the fluid coolant may have contact for a longer duration with the structures 222 and 232, which can improve cooling efficiency. The conformal structures 222, 232 may use less material and occupy less space than the structures 202, 212 and thus be more suitable for some implementations.

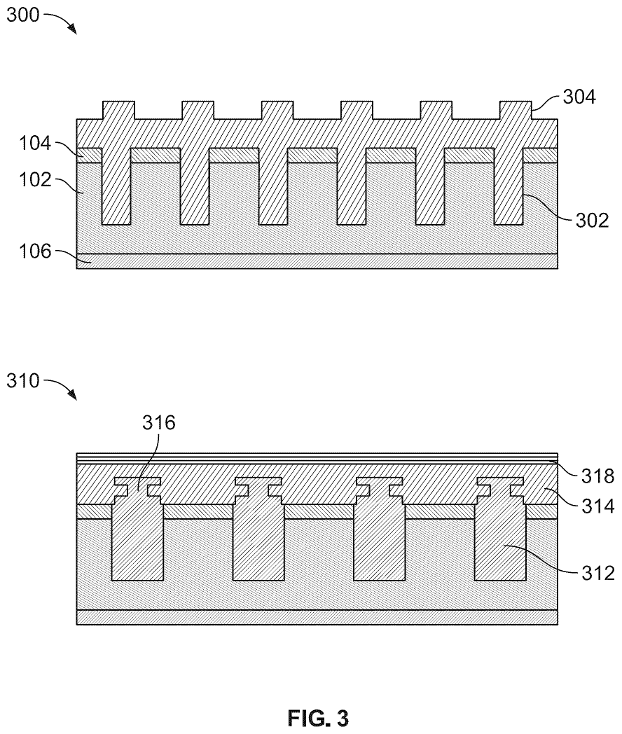

In some embodiments, the integrated thermal exchanger may be a heterogeneous exchanger comprising two or more thermally conductive materials. For example, the heterogeneous exchanger may be formed such that the portion with higher thermal conductivity is exposed to the chamber volume. FIG. 3 shows schematic side views of exemplary structures 300, 310 including a heterogeneous integrated thermal exchanger, in accordance with some embodiments of the disclosure. In the structure 300, a portion of the heterogeneous exchanger extends into the device 102 using a plurality of thermal vias 302 comprising a first thermally conductive material. For example, the thermal vias 302 may include copper, copper-based alloy, diamond, etc., disposed using a first deposition process such as an electrochemical process. The first process may be applied to at least partially fill blind cavities etched into the device 102. The heterogeneous exchanger includes an upper portion 304 comprising a second thermally conductive material. For example, the upper portion 304 may include diamond, carbon nanotubes, or another thermal conductor deposited using a second electrochemical process. The second process may be applied to overfill the blind cavities in the device 102 and/or to coat over the substrate surface. The exposed side of the upper portion 304 may be patterned and/or shaped to enhance heat transfer with fluid coolant. Some non-limiting examples of the upper portion 304 include a diamond-based die bonded to the device's surface, a carbon nanotube coating, diamond or carbon particulates, metal-diamond composites, and/or diamond-like carbon (DLC) films. Some example processes to form the upper portion 304 include vacuum deposition (e.g., physical vapor deposition (PVD), chemical vapor deposition (CVD), plasma-enhanced deposition techniques), printing, thermal spraying, electrolytic or electroless techniques, and/or spin coating. It is noted that the listing of processes provided herein is illustrative and non-exhaustive. It is contemplated that any suitable process to form the heterogeneous exchanger may be applied without departing from the teachings of the present disclosure.

Structure 310 includes a heterogeneous exchanger bonded to a substrate or a device such as device 102. Reference to the device 102 is provided in the following paragraphs for illustrative purposes and is intended to be non-limiting. As shown in the structure 310, the heterogeneous exchanger includes the thermal vias 312 extending into the device 102 and an upper portion comprising a device 314 bonded to the device 102. Thermal vias 312 comprise a first thermally conductive material and the device 314 comprises a second thermally conductive material. In some embodiments, a bonding layer (not shown) is disposed between the device 314 and the device 102. As shown in the structure 310, the device 314 may be directly bonded to the device 102. For example, the device 314 may be a diamond-based die that is bonded to the device 102 using a suitable direct-bonding or hybrid-bonding technique. In structure 310, the device 314 may be hybrid-bonded (e.g., using DBI) to exposed sides of the thermal vias 312 using bonding structures such as bonding pads 316. Bonding pads 316 may help bond the device 314 and the device 102 in a compact manner. In some embodiments, the device 314 may comprise active and/or passive circuit components. Some of the bonding pads 316 of the device 314 may be electrically coupled or bonded to thermal vias or vias that also serve as electrodes connecting the device 314 to the BEOL layer of the substrate 106. A protective layer 318 may be optionally disposed over the device 314 to prevent corrosion or other damage due to interactions with a fluid coolant in some implementations.

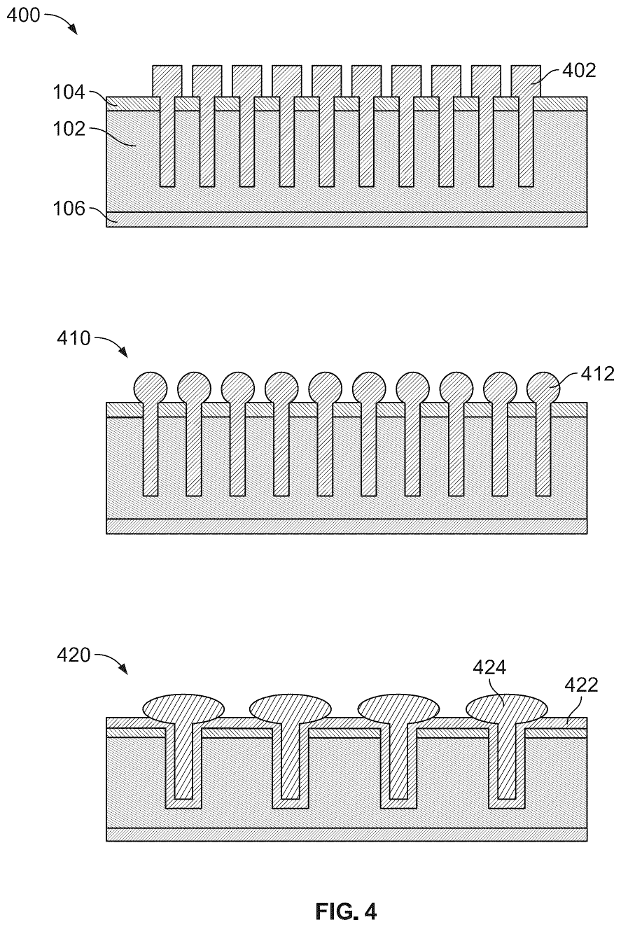

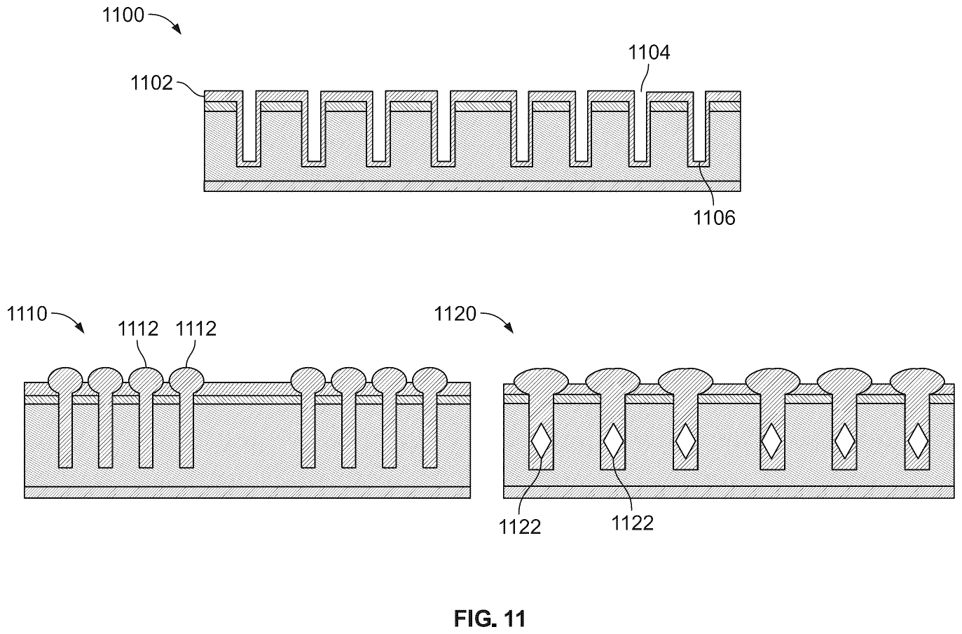

In some embodiments, some upper portions of a thermally conductive structure are removed, leaving parts of the substrate surface or dielectric layer exposed. FIG. 4 shows schematic side views of exemplary devices such as structures 400, 410, 420 having shaped thermal vias, in accordance with some embodiments of the disclosure. Structure 400 may be formed by etching, for example, the structure 210 to leave gaps between upper portions of the thermal vias 402. Structures 410 and 420 may be formed by overfilling the blind cavities in the device 102. In some embodiments, the thermal vias 402, 412, and 424 may represent an array of vias in a grid or other arrangement when viewed from above the device. For example, the array of vias may be arranged in concentric rings, zig-zags, or other suitable geometric patterns and configurations. Alternatively, the thermal vias 402, 412, and 424 may represent continuous rows on a side. Structures 400, 410, 420 include examples of shaped upper portions of the thermal vias. Structure 400 includes the thermal vias 402 having rectangular (e.g., square) portions. Structure 410 includes the thermal vias 412 having substantially spherical portions. Structure 420 includes a conformal coating 422 and the thermal vias 424 having ovoid portions. The coating 422 and the thermal vias 424 may comprise different thermally conductive materials as discussed with respect to FIG. 3. Although not shown in FIG. 4, the upper portions of thermal vias 402, 412, and 424 may be roughened and/or coated with an anti-corrosion layer. It is contemplated that other suitable shapes may be implemented to enhance cooling efficiency of the overall structure. Thermal vias 402, 412 and 422 may comprise occluded voids or elongated voids within thermal vias 402, 412, 422 as further discussed with respect to FIG. 11. The elongated void within a thermal via may reduce the stress generated by the presence of the thermal vias in a substrate.

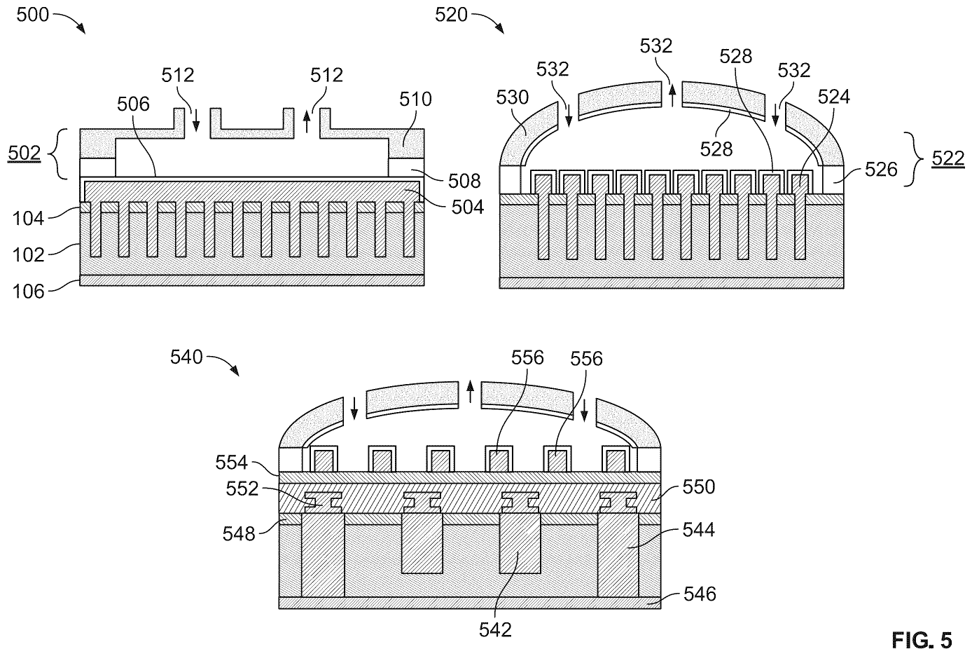

The thermal exchanger or a portion thereof may be disposed in a fluid chamber. In some embodiments, the housing of the fluid chamber is shaped and modified to enhance the cooling efficiency of the overall assembly. FIG. 5 shows schematic side views of exemplary fluid-cooled microelectronic assemblies 500, 520, 540 including a thermal exchanger disposed in a shaped fluid chamber, in accordance with some embodiments of the disclosure. Although not shown in FIG. 5, it is contemplated that the housing of the fluid chamber may be attached to the sides of a base substrate in the microelectronic assembly in some embodiments. Assemblies 500, 520, and 540 may depict different configurations of a fluid-cooled device or module. For example, assembly 500 may be bonded to a device, substrate, routing layer, or a redistribution layer via layer 106.

Assembly 500 includes a thermal exchanger 504 and a fluid chamber 502 having a housing 510 attached to the thermal exchanger 504 via a bond 508. For example, the housing 510 may be attached to the top portion of the thermal exchanger 504. Thermal exchanger 504 extends into the device 102 via a plurality of thermal vias. Protective layer 506 is optionally disposed over at least the portion of thermal exchanger 504 disposed inside the fluid chamber 502 in preparation for protecting against damage due to a fluid coolant. Thermal exchanger 504 is shown as substantially smooth but may be patterned and/or shaped in other implementations. Bond 508 may include an adhesive or other bonding technique forming a leakproof seal such that fluid coolant does not leak out of the fluid chamber 502. For example, the bond 508 may include a hybrid bond via an intervening bonding layer between housing 510 and thermal exchanger 504. Bond 508 may be disposed along the surface perimeter of the thermal exchanger 504. Housing 510 may comprise a material that is sufficiently resistant to fluid coolant and fluid pressure. For example, housing 510 may be a metal or a ceramic with a protective coating. Fluid chamber 502 includes fluid pipes 512 to allow flow of fluid coolant into housing 510. For example, the fluid pipes 512 may be connected to an external pump or fluid-cooling system. Housing 510 may be joined at right angles to form a rectangular, box-like fluid chamber. However, such a configuration can disturb the fluid flow proximate to the corners of housing 510 and may result in formation of air pockets or bubbles inside fluid chamber 502, limiting the cooling efficiency. It may be preferable to modify and/or shape the housing to discourage bubble formation, for example, as shown in assemblies 520 and 540.

Assembly 520 includes a thermal exchanger comprising thermal pillars 524 disposed in a curved fluid chamber 522 having a housing 530. A protective coating 528 is optionally disposed over portions of thermal pillars 524 that would be exposed to fluid coolant inside fluid chamber 522. In some embodiments, the housing 530 of the fluid chamber 522 is bonded to the side of device 102 as represented by bond 526. For example, the housing 530 may be bonded to dielectric layer 104. It is contemplated that a suitable bonding technique may not require an intervening layer to bond the housing 530 and the device 102. Fluid chamber 522 includes curved housing 530 and fluid pipes 532. Inner walls of housing 530 are optionally coated with a protective coating 528. The coating on thermal pillars 524 may be the same material or a different material than the coating on housing 530. For example, thermal pillars 524 may be protected using an anti-corrosive coating, and housing 530 may be fluid proofed by a resin coating. The coating on thermal pillars 524 is selected to have decreased interference on the heat transfer between thermal pillars 524 and a fluid coolant in fluid chamber 522. Housing 530 is curved to reduce or eliminate entrapment of air bubbles near to the walls of housing 530 and may suppress formation of air bubbles inside fluid chamber 522. As shown in FIG. 5, the fluid pipes 532 are configured to include two inlets at the sides and one outlet around the middle for fluid coolant. Such a configuration may encourage opposing fluid flows over thermal exchanger, particularly thermal pillars 524, which may increase exchanger-coolant contact duration near the expected hot spots and enhance the overall cooling efficiency. It is contemplated that assembly 520 depicts one fluid pipe configuration, and other fluid pipe configurations may be suitably implemented for the same or similar purpose.

Assembly 540 includes a heterogeneous exchanger extending into the device 102 and enclosed inside a curved fluid chamber such as fluid chamber 522. Layer 548 is disposed over a first side of the device 102. For example, the layer 548 may be a dielectric layer such as the dielectric layer 104. In some embodiments, the layer 546 is disposed over a second side of the device 102 that is opposite to the first side. Layer 546 may comprise power and/or ground traces.

The heterogeneous exchanger is disposed over layer 548 with vias 542, 544 extending into the device 102. The heterogeneous exchanger includes thermal vias 542, thru vias 544, upper portion 550, bonds 552, layer 554, and thermal pillars 556. The vias 544 may be grounding and/or power vias. For example, one or more of the vias 544 may be coupled to a ground, and one or more other vias of the vias 544 may be coupled to power. Thermal vias 542 fill blind cavities in the device 102 that stop at a level before reaching the second side of the device 102. The vias 544 may fill a thru-via cavity that extends through the device 102 at the periphery, starting from the first side of the device 102 and stopping at the second side of the device 102. In some embodiments, vias 544 may be coupled to the power and/or ground traces in the layer 546. Upper portion 550 is disposed over the layer 548. Upper portion 550 may comprise a material having a higher thermal conductivity than the thermal vias 542. For example, the upper portion 550 may comprise a diamond die surrounded with a protective film. Upper portion 550 is bonded to the thermal vias 542 and/or the vias 544 using a bond 552. For example, the bond 552 may include interconnect pads in the upper portion 550 directly bonded to the sides of the thermal vias 542 and the vias 544. Layer 554 is disposed over the upper portion 550 and may provide a surface to which the housing of the curved fluid chamber is attached. Layer 554 may be a second dielectric layer, for example, designed to enhance the adhesion for the housing of the fluid chamber. Pillars 556 may be thermally conductive features (e.g., protrusions) patterned or disposed on layer 554. In some embodiments, pillars 556 are coated with an anti-corrosive material. In some embodiments, the pillars 556 may comprise the same TC material or a different TC material than the thermal vias 542. Although not shown in FIG. 5, in some embodiments, the pillars 556 may comprise the same thermally conductive material as device 550 or a third thermally conductive material.

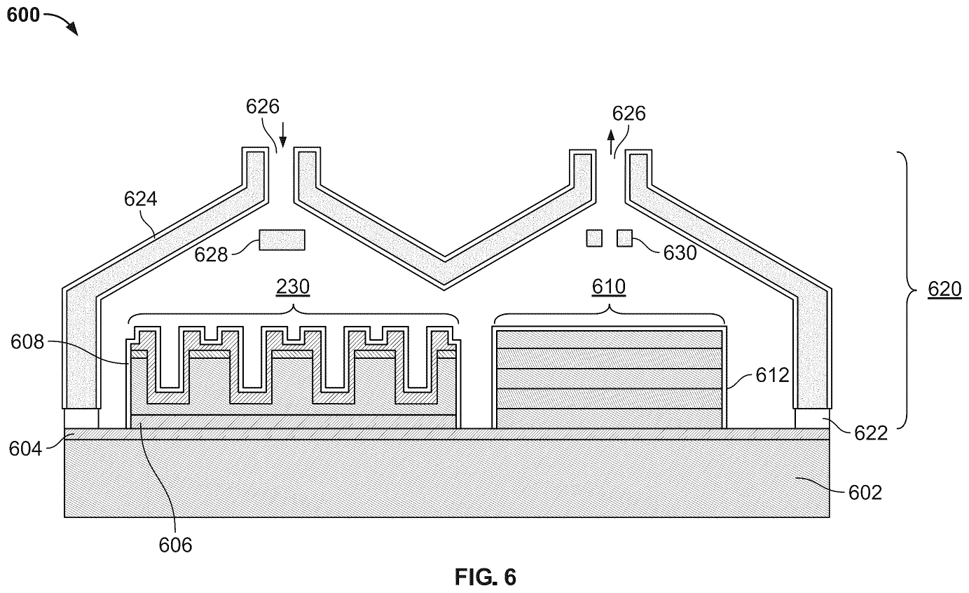

In some embodiments, the thermal exchanger is disposed in the fluid chamber, where the housing of the fluid chamber encloses the thermal exchanger and one or more devices, allowing fluid coolant to simultaneously cool the enclosed devices. FIG. 6 shows a schematic side-view of an exemplary microelectronic assembly 600 with two enclosed devices such as a structure 230 and a device stack 610, in accordance with some embodiments of the disclosure. Assembly 600 includes the structure 230 and the device stack 610 disposed on a substrate 602 and inside the fluid chamber 620. In some embodiments, substrate 602 may comprise or be an interposer. Exposed sides of the structure 230 and the stack 610 are optionally coated with respective protective layers 608 and 612. Protective layers 608 and 612 are configured to prevent damage due to structure 230 and stack 610 having contact with a fluid coolant. Structure 230 and device stack 610 may be bonded to the substrate 602. For example, the layer 606 may be used to bond the structure 230 to layer 604. Device stack 610 may be a vertical stack of devices. At least one device may be bonded to a successive device in the stack 610 (e.g., via direct bonding or hybrid bonding). For example, stack 610 may be a three-dimensional integrated circuit device stack having three devices where at least the first device and the second device are bonded together. The housing of fluid chamber 620 encloses structure 230 and stack 610 and may be shaped to suppress air bubble entrapment in a fluid coolant. Structure 230 is shown as an example. It is contemplated that any number of the devices and structures in the present disclosure may be included in assembly 600.

Fluid chamber 620 includes a bond 622, shaped housing 624, fluid pipes 626, and flow modifiers 628, 630 (e.g., shower heads). Fluid chamber 620 may be attached to the layer 604 on the substrate 602 using the bond 622. For example, the bond 622 may represent a dielectric bonding layer. In another example, the bond 622 may be a nonporous adhesive. It is noted that the bond 622 may be any suitable bonding or adhesion technique such that fluid coolant would not leak out of the fluid chamber 620. For example, the bond 622 may form a hermetic seal between the housing 624 and the substrate 602. Housing 624 includes walls joined at obtuse angles that may suppress air bubble entrapment and/or result in a shaped housing that encourages flow proximate to the walls. While not shown, one or more stiffeners may be attached to the outer walls of housing 624 or embedded into housing 624 as discussed with respect to FIG. 1. Housing 624 may be thinly coated with a Ni-based alloy as discussed with respect to FIG. 1. Other structural supports may be added to resist the fluid pressure and prevent warpage to housing 624. Fluid pipes 626 are connected to the top of housing 624. In some embodiments, fluid pipes 626 may be connected at another region of housing 626 (e.g., at the sidewalls). Coolant flow from fluid pipes 626 may need to be adjusted upon entering fluid chamber 620 by flow modifiers 628 and 630. For example, modifier 630 may include a diffuser component to reduce the flow velocity of outgoing fluid coolant, and modifier 628 may include a tunable nozzle for the incoming fluid coolant. Other suitable devices for adjusting and tuning the fluid flow may be applied. Assembly 600 may be used to simultaneously cool multiple enclosed devices. The cooling efficiency of the devices may be improved by including a thermal exchanger as in structure 230.

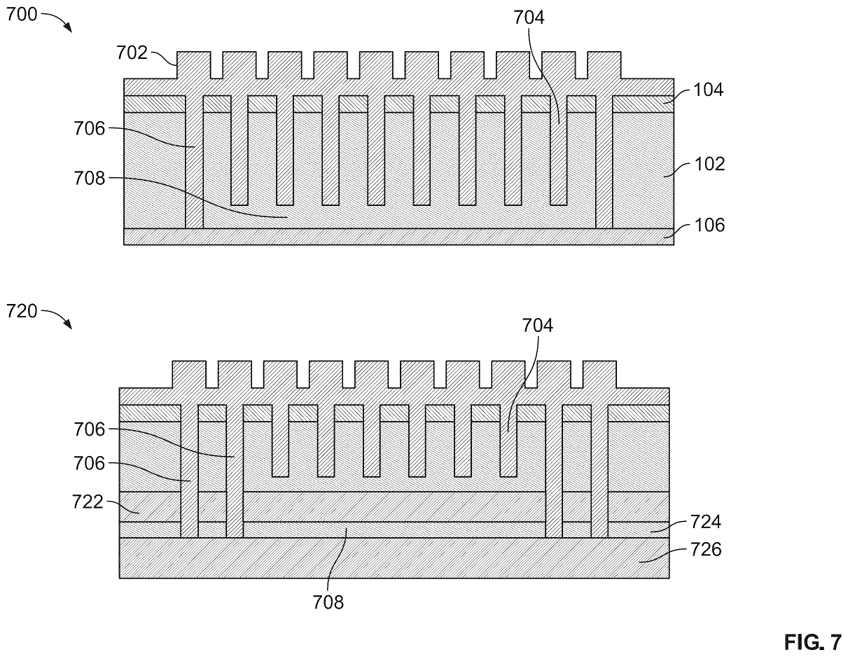

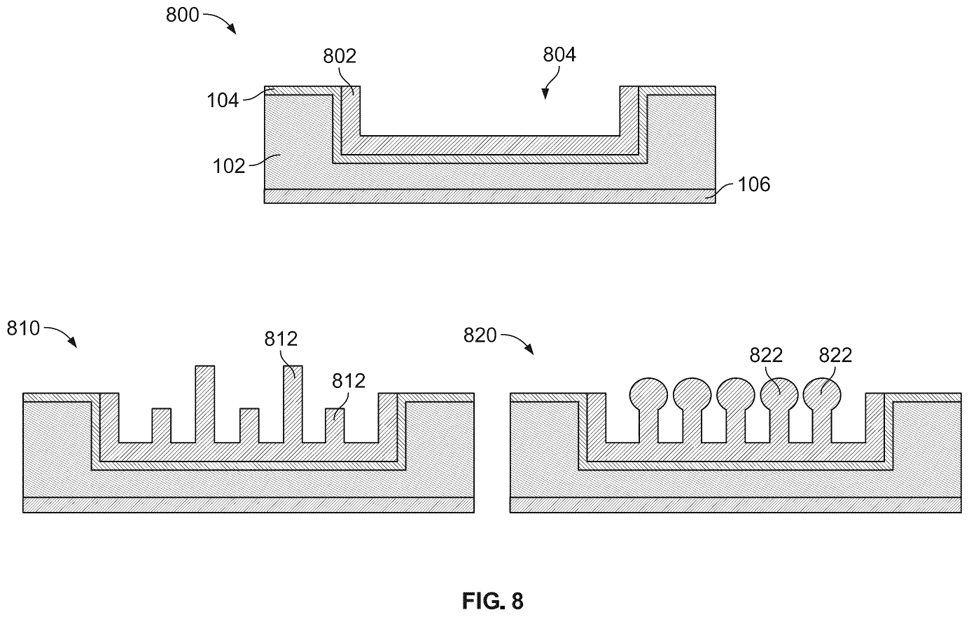

In some embodiments, one or more power or grounding vias (collectively referred to as “thru vias” for brevity) are included in a thermal exchanger. For example, the thru vias may provide an electrical conduction pathway that prevents charge buildup on the thermal exchanger. Additionally, a fluid-cooled device, such as in FIGS. 2-4, may be stacked to a second substrate or device. FIG. 7 shows schematic side views of exemplary microelectronic stacks 700, 720 including a thermal exchanger 702, in accordance with some embodiments of the disclosure. Stack 700 includes the thermal exchanger 702 and a device region 708. Thermal exchanger 702 comprises a patterned upper portion or surface, a plurality of thermal vias 704, and thru vias 706. As an illustrative example, the device region 708 may represent the primary hot region in the stack 700. For example, the device region 708 may comprise components and/or integrated circuitry that generates a majority of the heat to be extracted. Thermal vias 704 may be placed in the inner portion of the stack 700, stopping near to the device region 708. In some embodiments, the thermal vias 704 enter or surround the device region 708 without interfering with the device operation, stopping before reaching the front side of the device 102. An electrical isolation barrier may surround the thermal vias 704 to prevent electrical coupling with circuitry in the device region 708. Thru vias 706 may be placed at the periphery in stack 700, extending through the device 102 to stop at the front side. For example, to ground the thermal exchanger 702, the thru vias 706 may be coupled to grounding traces at the layer 106. In some embodiments, the thru vias 706 may be disposed near inner regions of the thermal exchanger 702. For example, the microelectronic stack may include multiple device regions. Thru vias 706 may be located near the center of the stack 700 in between two or more device regions. Thru vias 706 may contact pads on a second substrate by extending past the layer 106 as shown in the stack 720.

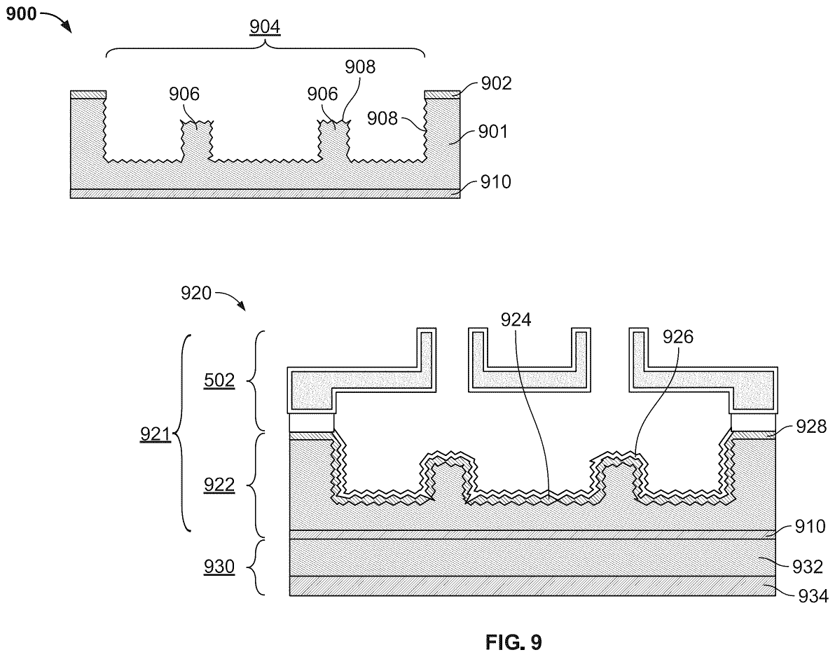

Stack 720 includes a modification of the thermal exchanger 702. Stack 720 includes the thermal vias 704 and the thru vias 706. Exchanger 702 may be part of an upper portion of the stack 720. Stack 720 includes a second substrate 724 bonded to the upper portion via a layer 722. For example, the layer 722 may include a routing layer that is bonded to the upper portion and the substrate 724. Substrate 724 includes a device region 708 and a second layer 726 at the bottom of stack 720. Additional devices and/or structures may be added via layer 726. In some embodiments, the device 102 and the substrate 724 have separate device or hot-spot regions. Thermal vias 704 may be suitably modified to extract heat from both device regions. For example, some vias of the thermal vias 704 in the stack 720 may extend past the device 102 and stop near device region 708 in substrate 724. The extended vias stop at a level before reaching the bottom of stack 720. Additionally, or alternatively, a combination of thermal exchangers may be included on different substrates in stack 720 to build a thermal path that leads to the patterned side on the back side of thermal exchanger 702. For example, stack 700 may be disposed on the structure 200. Stacks 700 and/or 720 may be part of a fluid-cooling module as described with respect to FIG. 9.

In some embodiments, a conformal thermal exchanger is disposed in a cooling blind cavity. For example, the cooling blind cavity may have a greater cavity width than the cavity height (e.g., a width-to-height aspect ratio greater than one). Such a cavity may be referred to herein as a wide cavity. The surfaces of the cavity may be roughened, patterned, textured, etc., to enhance the thermal exchange between fluid coolant and the conformal thermally conductive structure. FIG. 8 shows schematic side views of exemplary devices 800, 810, 820 including a conformal thermal exchanger disposed within a wide cavity, in accordance with some embodiments of the disclosure. Device 800 includes an exchanger 802 disposed inside a cavity 804. Layer 104 may be disposed within cavity 804 between the device 102 and the exchanger 802. For example, the layer 104 may provide a bonding surface (or side) for exchanger 802. In some embodiments, the layer 104 may surround the cavity 804. For example, the layer 104 may be a dielectric layer, a barrier coating, etc., that electrically isolates the device 102 from the exchanger 802. Layer 104 may prevent diffusion of material between the exchanger 802 and the device 102. In some embodiments, an opening (not shown) may be defined in the layer 104. Exchanger 802 extends into device 102 starting from a level above the device 102 and stopping at a level before reaching the bottom surface of the device 102. The exchanger 802 may be modified and/or shaped for fluid cooling. In some embodiments, the exchanger 802 is an intermediate structure in the process of forming a thermally conductive structure. For example, the exchanger 802 may be used as a seed layer or a conductive coating to form additional features as shown in the devices 810, 820. The thermal exchanger may comprise a material having a higher thermal conductivity than silicon. For example, the exchanger 802 may comprise copper, diamond, carbon nanotubes, etc. In some embodiments, the thermal exchanger is a heterogeneous structure comprising multiple layers. For example, the exchanger 802 may include a first layer comprising copper and a second layer comprising diamond particulates disposed on the first layer. For example, when the exchanger 802 comprises multiple layers, the top layer (e.g., the diamond particulates) may be modified to form pillars 812, 822 in respective devices 810, 820.

Device 810 includes a plurality of thermal pillars 812 extending away from exchanger 802. As shown, some vias of thermal pillars 812 extend out of cavity 804 while other vias of thermal pillars 812 stop before reaching the height of cavity 804. For example, thermal pillars 812 may be in rows along the side of exchanger 802 and/or an array of columns extending outwards. In some embodiments, thermal pillars 812 may be formed in various shapes and dimensions (height, width, shape, etc.). The variations in thermal pillars 812 may enhance heat exchange with fluid coolant, thus improving the cooling efficiency. For example, device 820 includes shaped thermal pillars 822. Thermal pillars 822 have rounded upper portions to improve cooling efficiency.

In some embodiments, the thermal exchanger comprises a textured and/or roughened fluid cavity surface to enhance heat exchange with fluid coolant as discussed with respect to FIG. 9. The exchanger may be part of a fluid-cooling module (e.g., a cooling head apparatus) that is attachable to a second device. FIG. 9 shows schematic side views of an exemplary microelectronic assembly including a roughened, conformal thermal exchanger, in accordance with some embodiments of the disclosure. FIG. 9 shows a thermal exchanger 900 and a fluid-cooling module 920 including a cooling head 921 with a thermal exchanger 922 having a textured cavity inner surface. Exchanger 900 includes a thermally conductive substrate 901. The substrate 901 may comprise a material that is more thermally conductive than silicon (e.g., a metal-diamond composite). In some embodiments, substrate 901 comprises an integrated circuit device. The device may be disposed in substrate portions that are offset but near to the thermal pathway such that there is minimal interference. Cavity 904 is etched into the substrate 901 starting from the back side and stopping at a level before reaching the opposing front side of the substrate 901. Cavity 904 may be shaped to include a patterned topography such as mounds 906. In some embodiments, the exposed sides inside the cavity 904 are patterned (e.g., via etching, lithography, electrochemistry, etc.) to form a textured side 908. Layer 902 is disposed on the upper surface of the substrate 901 at the periphery. Layer 902 may be provided as a surface for attaching a housing of a fluid chamber, for example, the housing of fluid chamber 502 as shown in module 920 at FIG. 9. For example, the layer 902 may be a dielectric layer prepared for bonding. Layer 910 is disposed on the front side of the substrate 901. Layer 910 may provide a surface for bonding the module 920 to a second device such as a device 930. For example, the layer 910 may be a layer suitably prepared for hybrid bonding.

Exchanger 900 may be part of a fluid-cooling module such as the exchanger 922 in the fluid-cooling module 920. Exchanger 922 coupled to the housing of fluid chamber 502 may form the cooling head 921. Exchanger 922 includes a layer 924 disposed over the textured side 908 inside the cavity 904. As an illustrative example, the layer 924 may be extended from the layer 902 at the periphery and may comprise the same material as the layer 902. In some embodiments, the layer 924 may comprise a different material than the layer 902. For example, the layer 924 may be a thermally conductive coating of a different material than layer 902 formed by spraying diamond particulates over the textured side 908. In some embodiments, protective layer 926 is disposed over layer 924 to protect against damage from fluid coolant inside fluid chamber 502. The textured side 908 and mounds 906 may provide surfaces that enhance turbulent fluid flow to efficiently extract heat and interact with fluid coolant inside cavity 904.

In some embodiments, the thermal exchanger 922 may be a heterogeneous structure comprising two or more thermally conductive materials, where the more thermally conductive material is coated on the inner walls of the exchanger 922. For example, the substrate 901 may comprise silicon at or near the front side and copper and/or diamond layer(s) coated on the inner walls of the cavity 904. In this example, the mounds 906 may comprise topographical features formed for enhancing cooling efficiency within inside cavity 904. The overall thermal path may be more efficient by including highly thermally conductive materials in the exchanger 922 at particular locations near hot-spot regions.

Module 920 includes the housing of fluid chamber 502 attached to the upper surfaces 928 of the exchanger 922 to form the cooling head 921. For example, the housing 510 of fluid chamber 502 may be bonded to the surfaces 928 using a suitable adhesion or bonding technique such that fluid coolant cannot leak out of the fluid chamber 502 and expose the inner surface of thermal exchanger 922 to the fluid chamber 502. For example, fluid coolant introduced into the fluid chamber 502 may interact with the exchanger's inner surface. Fluid chamber 502 is provided as an illustrative example. Another fluid chamber may be formed or attached without departing from the teachings of the present disclosure. Module 920 may include a device 930 bonded to the front side of the cooling head 921 via layer 910. Device 930 includes a front side layer 934. For example, the layer 934 may comprise a redistribution layer. For example, the layer 934 may comprise a bonding and/or BEOL layer for forming a device stack. In the module 920, the device 930 may include a primary heat-generating region such as a device region 932. Device region 932 may include active circuitry or other electronic heat-generating components. In embodiments where the substrate 901 of cooling head 921 comprises a device region, the module 920 may be configured such that the device region 932 generates substantially more heat compared to the device region of cooling head 921. Cooling head 921 may be configured to extract the heat from device 930. Cooling head 921 may conduct the heat to fluid coolant in the fluid-cooling cavity. In some embodiments, the fluid coolant flows out of cooling head 921 to a heat sink or chiller (not shown). The chiller may extract most of the heat from the incoming coolant and the cooling head 921. In some embodiments, the coolant, after the heat extraction, is recirculated through the cooling head 921 in a closed-loop configuration. In some embodiments, thermal pillars (not shown) may extend from the exchanger 922 and penetrate inside the device region 932 without reaching layer 934. Module 920 may be part of an apparatus for fluid cooling devices without disposing the devices in a fluid chamber via the cooling head 921.

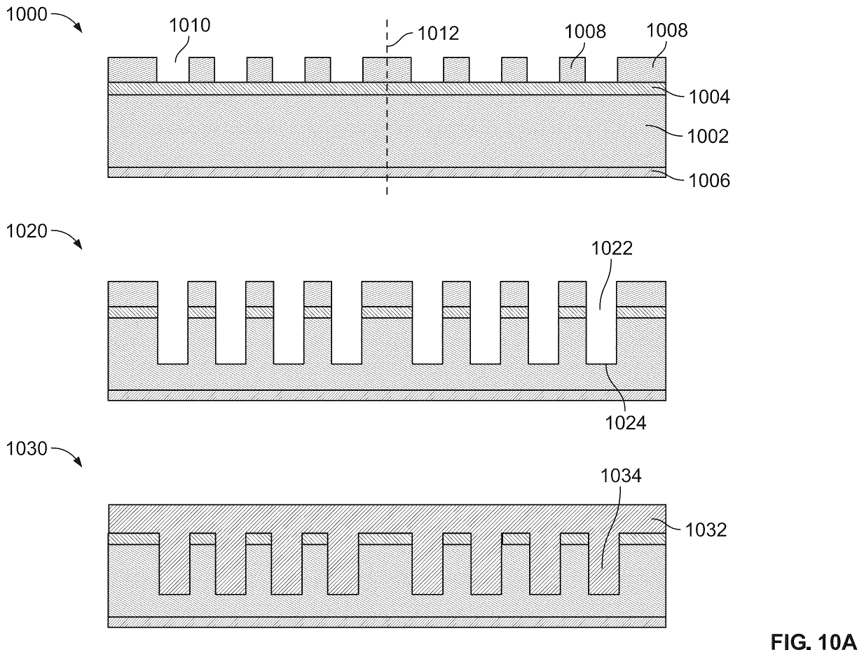

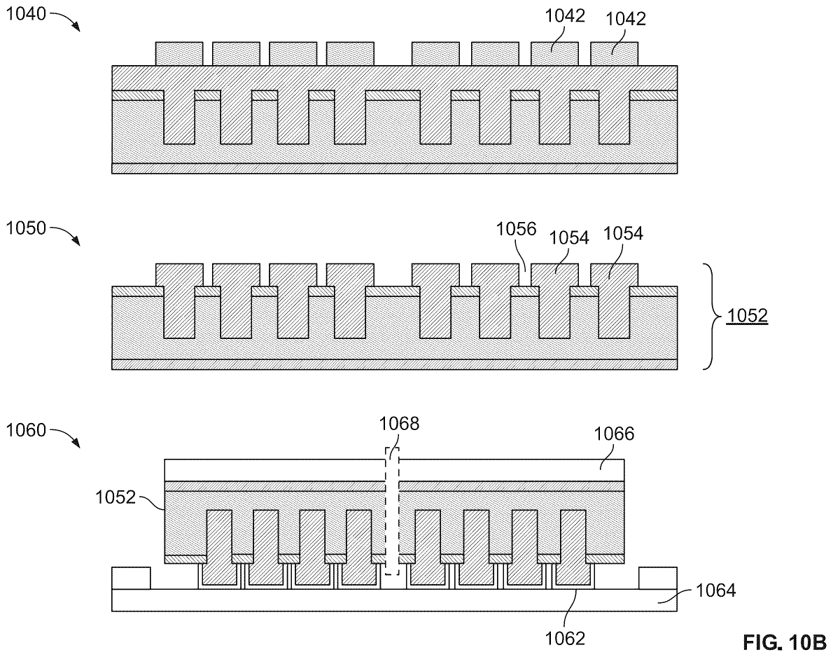

Exemplary processes for manufacturing the thermal exchanger are described in FIGS. 10-12. FIGS. 10A-B (collectively, FIG. 10) show schematic side views outlining an exemplary process for forming a thermal exchanger, in accordance with some embodiments of the disclosure. FIG. 10A shows exemplary structures that may be formed as part of manufacturing the thermally conductive structure. At step 1000, a device, wafer, or substrate 1002 is provided and referred to as substrate 1002 for brevity. For example, substrate 1002 may comprise a device, integrated circuitry, and/or other electronic components. Substrate 1002 may be marked for singulation as indicated by singulation line 1012, defining first and second sections of the structure. While two sections are shown, it is noted that the structure may be singulated into any number of sections. Layer 1004 is disposed over a first side of the substrate 1002 such as the back side. For example, the layer 1004 may be the dielectric layer 104. A second layer 1006 is disposed over a second side of the substrate 1002 such as the front side. For example, the layer 1006 may be a BEOL dielectric layer. Layers 1004 and 1006 may be prepared and cleaned to provide a suitably smooth surface, for example, as a bonding surface.

Resist layer 1008 may be disposed over the layer 1004. Resist layer 1008 is patterned to form gaps 1010, leaving portions of the layer 1004 exposed. Gaps 1010 provide a suitable pattern to support a selective etching process, for example, to form a plurality of cavities for the thermal vias 114 or a wide cavity (e.g., cavities 804, 904). At step 1020, blind cavities 1022 are etched at the exposed portions of layer 1004, extending into the substrate 1002. Cavities 1022 stop at a level 1024 inside the substrate 1002 before reaching the second side of the substrate 1002. In some embodiments, the selective etching process may include more than one phase. For example, the wide cavity 804 may be etched in a first phase. A resist layer pattern may be disposed inside the wide cavity and then further etched in a second phase to form the cavity 904 with the mounds 906.

At step 1030, resist layer 1008 is removed and the structure is cleaned. A liner, barrier, or other intermediate layers may be disposed over the layer 1004 and inside cavities 1022. For example, a diffusion barrier may be disposed over the walls of cavities 1022. As another example, a thin adhesion film may be disposed over the layer 1004 and the walls of cavities 1022 to improve the stability of a thermal exchanger. After preparing the structure, a thermal exchanger 1032 is formed by disposing a thermally conductive material (e.g., metal, diamond, carbon nanotubes, etc.) over layer 1004 and in cavities 1022, filling each cavity down to the level 1024 and forming thermal vias 1034. Exchanger 1032 extends into the substrate 1002 starting from above the layer 1004 and stopping at the level 1024 before reaching the second side of substrate 1002. In some embodiments, the exchanger 1032 may be planarized, coated with a protective layer, and/or singulated along line 1012. In some embodiments, a fluid chamber may be formed by coupling a housing of the fluid chamber to the exchanger 1032 (e.g., by attaching the housing to the exchanger 1032 or the singulated sections).

In some embodiments, the exchanger 1032 may be further patterned, modified, and designed to enhance fluid coolant interactions and thus improve cooling efficiency. FIG. 10B shows exemplary structures that may be part of a process for forming a thermal exchanger having a patterned upper portion. At step 1040, a second resist layer 1042 is disposed over portions of the exchanger 1032, leaving space for etching a pattern into the exposed upper portion of the exchanger 1032. For example, as shown at step 1040, a resist layer 1042 is disposed directly over the portions where the thermal vias 1034 extend into the substrate 1002. Resist layer 1042 is not limited to bounds defined by extending an imaginary line along the cavity walls and may be disposed over a portion of the layer 1004 adjacent to the cavities 1022. At step 1050, the upper portion of the exchanger 1032 is etched to form a thermal exchanger 1052, stopping at the surface of the layer 1004. In some embodiments, patterning the upper portion of the exchanger 1032 may include partially etching the exposed upper portion and stopping before reaching layer 1004 (e.g., as in structure 210). Exchanger 1052 comprises upper portions 1054 of the thermal vias 1034, where the upper portions 1054 are spaced apart by gaps 1056. Upper portions 1054 may be modified further for fluid cooling (e.g., shaped, smoothed, roughened, textured, etc.). At step 1060, the upper portions 1054 are coated with a protective layer 1062 to prevent damage and/or contamination of the upper portions 1054. For example, the protective layer 1062 may be a layer to prevent damage due to contact with a fluid coolant. In embodiments where the thermal exchanger is further singulated, the exchanger 1052 may be flipped (e.g., as shown in FIG. 10B) such that the coated ends of the upper portions 1054 are placed on a carrier or singulation frame 1064. Layer 1066 may be disposed over the layer 1006, for example, to prevent contaminating a bonding surface during singulation. Additionally, or alternatively, the layer 1066 may be a structural support layer, for example, to prevent warpage and/or flatten the exchanger 1052. Exchanger 1052 is singulated at line 1068 to form singulated thermal exchangers 1052. Layer 1066 is removed, and the layer 1006 of each singulated exchanger 1052 may be prepared and/or cleaned (e.g., for bonding) before removing the frame 1064 and reorienting the structure. For example, the process of FIG. 10 may be applied to form structure 400 or the like.

In some embodiments, forming a thermal exchanger may include depositing a conformal thermally conductive layer, for example, as a seed layer. FIG. 11 shows schematic side views of exemplary structures 1100, 1110, 1120 including a conformal and/or shaped thermal exchanger, in accordance with some embodiments of the disclosure. For example, cavities 1104 may be formed in the substrate 1002 as discussed regarding FIG. 10A. After removing the resist layer 1008, a conformal layer 1102 may be disposed over the layer 1004 and the sides of the cavities 1104 down to a level 1106 at the bottom of the cavities 1104. Level 1106 may be located near to a heat-generating region (e.g., an active circuitry region) of the substrate 1002. For example, a thermally conductive conformal or nonconformal layer 1104 may be a thermal exchanger in a fluid-cooled assembly such as the structure 220. Layer 1102 may be a base layer for forming a thermal exchanger (e.g., a seed layer for plating a metal). Layer 1102 may be used to at least partially fill the cavities 1104 (e.g., using an electroplating or other chemical process) to form the thermal vias 1034. The same process or a second process may be used to overfill the cavities 1104 and form the upper portion of the exchanger 1032. Overfilling cavities may form topographical features (e.g., protrusions) extending out of the cavity openings. For example, shaped and/or curved upper portions 1112 in structure 1110 may be formed through such a process. In some embodiments, the upper portions 1112 comprise a thermally conductive material different from the layer 1102 (e.g., as shown in structure 420). Preferably, the thermally conductive material has a higher thermal conductivity than the layer 1102. In some embodiments, a thermal exchanger may include one or more voids (e.g., air gaps) in the vias extending into a device. For example, structure 1120 includes voids 1122 in the portions of thermal vias 1034 inside the device. Voids 1122 may be formed, for example, when filling cavities 1104 after depositing the layer 1102. Voids 1122 are contained within the portion of thermal vias 1034. It is noted that voids 1122 may of any suitable shape and/or size within thermal vias 1034. Voids 1122 may be suitably formed for reducing the stress generated by the presence of the thermal vias in a device. For example, the voids 1122 may balance stress from parts of the device surrounding the thermal vias 1034. In some embodiments, the layer 1102 may be sufficiently thick to form a thermal exchanger with the cavities 1104. For example, the layer 1102 may comprise a nickel-vanadium (NiV) alloy. In some embodiments, a thinner alloy may serve as a barrier and/or seed layer for the formation of a thicker thermally conductive structure and/or thermal vias. For example, the layer 1102 may be sufficiently thick to form thermal vias 224 without depositing additional conductive coating.

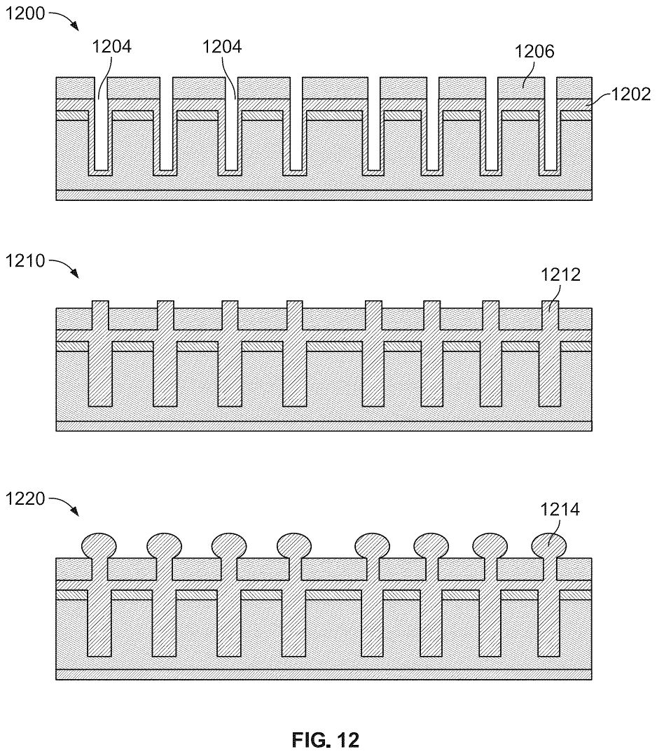

In some embodiments, a resist layer may be disposed over a conformal thermally conductive layer before filling cavities that extend inside a substrate or device, leaving gaps over the cavities. The cavities may be overfilled with one or more thermally conductive materials to a level above the resist layer. Such a process may form a thermal exchanger with upper portions that extend further into a fluid chamber's volume. FIG. 12 shows schematic side views outlining an exemplary process for forming a thermal exchanger with tall upper portions including techniques such as thru-mask plating, in accordance with some embodiments of the disclosure. The tall upper portions extend into a fluid chamber and may improve heat transfer with a fluid coolant. At step 1200, a patterned resist layer 1206 is disposed over a conformal thermally conductive layer 1202, leaving gaps 1204 over the cavities to expose the layer 1202. The exposed portions of the layer 1202 may be used as a seed layer. The cavities are filled with a thermally conductive material using a suitable technique such as a thru-mask plating process to form thermal vias inside the device and upper portions 1212. Upper portions 1212 may extend above the top side of the resist layer 1206. In some embodiments, the thickness of the resist layer 1206 may define the height of the upper portions 1212. For example, the upper portions 1212 may be formed below or up to the surface level of the resist layer 1206. In some embodiments, at step 1220, the upper portions 1212 are formed above the surface of the resist layer 1206 to form shaped upper portions 1214. Shaped upper portions 1214 may have topographical features including a mushroom-shaped or rounded top as shown at step 1220. Shaped upper portions 1214 may be additionally modified to pattern and design the exposed protrusions for enhancing fluid cooling efficiency (e.g., roughened). After forming the extended thermal pillars having the upper portions 1212 or the shaped upper portions 1214, the resist layer 1206 may be stripped from the structures 1210, 1220 prior to subsequent processing, for example, using a suitable solvent (e.g., a resist stripping developer solution) to expose the sides of the layer 1202 and/or the upper portions 1212, 1214.

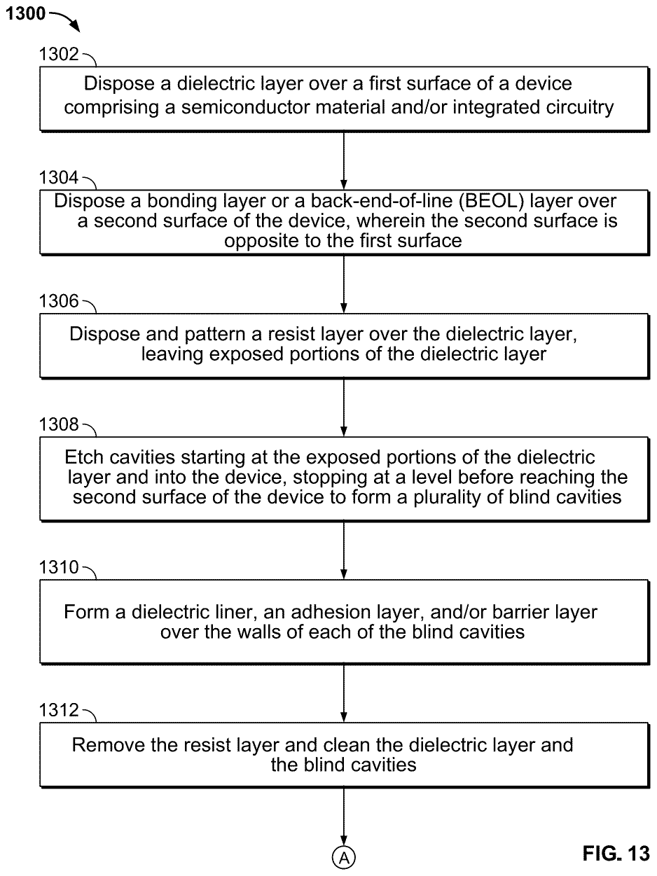

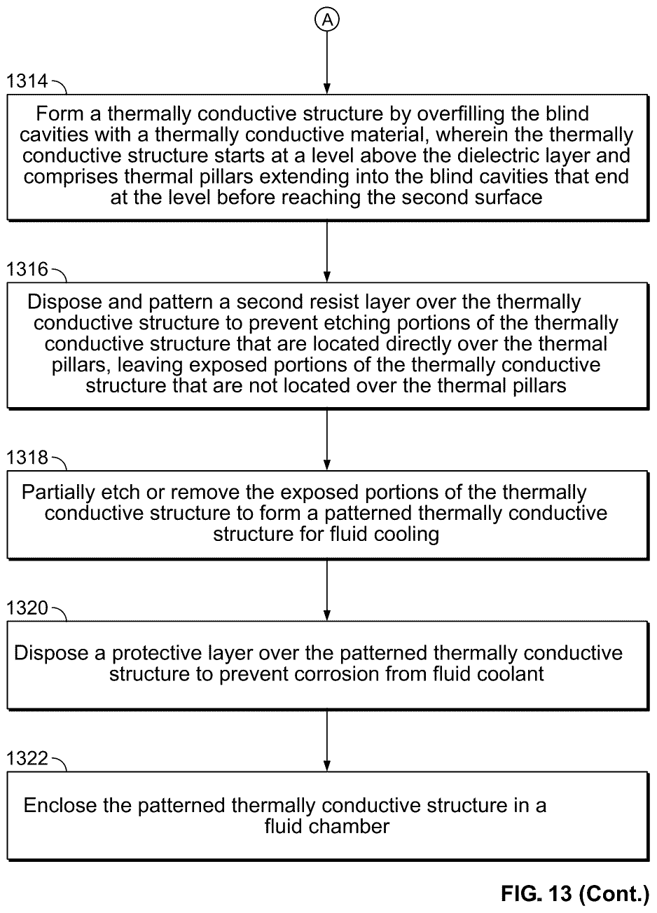

FIG. 13 is a flowchart of a process 1300 for forming and assembling a thermal exchanger for fluid cooling, in accordance with some embodiments of the disclosure. For example, process 1300 may be implemented to form structures 210 and 400. FIGS. 10-12 may show exemplary structures involved in process 1300. Starting at 1302, a dielectric layer is disposed over a first surface of a semiconductor device. For example, the device may comprise integrated circuitry at a hot-spot region. The device may comprise a semiconductor wafer. The device may be provided comprising a dielectric layer on the first surface. In some embodiments, the dielectric layer disposed over the first surface may comprise a smooth surface suitable for bonding. At 1304, a second layer is disposed over a second surface of the device. The second surface is opposite to the first surface. For example, the second layer may be a bonding layer, a BEOL layer, a second dielectric layer, etc. At 1306, a resist layer is deposited over the dielectric layer coated on the first surface. The resist layer may be suitably patterned for forming a thermal exchanger. For example, the resist layer may provide gaps or openings that leave exposed portions of the device and the dielectric layer. The resist layer may be used to support a selective etching process. At step 1308, cavities are etched into the exposed portions of the dielectric layer and into the device. The etch is stopped at a level before reaching the second surface of the device, resulting in one or more blind cavities. For example, a plurality of cavities may be etched for forming the thermal vias 114 or conformal structure 222. For example, a wide cavity (e.g., cavity 804) may be etched where the resist layer provides a gap that defines the cavity width. As an optional step at 1310, an intervening layer may be conformally disposed over the walls of the blind cavities and/or the dielectric layer surface. Some non-limiting examples include a dielectric liner, an adhesion layer, a diffusion barrier layer, etc. At step 1312, the resist layer is removed. The dielectric layer and interiors of the blind cavities are cleaned in preparation for forming a thermally conductive structure. At step 1314, a thermally conductive structure, or thermal exchanger, is formed by overfilling the blind cavities with a thermally conductive material. For example, the blind cavities may be filled with a metal such as copper. For example, the blind cavities may be filled with a DLC-carbon-based compound. Overfilling the blind cavities forms a thermal exchanger comprising: (i) an upper portion (e.g., portions 202 and 212) extending above the dielectric layer and disposed over the dielectric layer and (ii) a lower portion including thermal vias extending inside the blind cavities. The thermal exchanger starts at a level above the dielectric layer and extends into the cavities, stopping at the bottom surface of the cavities. The thermal vias stop at the level before reaching the second surface. In some embodiments, process 1300 may be halted, for example, to form structure 200.

In some embodiments, process 1300 may continue to step 1316. At step 1316, a second resist layer is disposed over the thermal exchanger. The second resist layer is patterned to prevent etching portions of the thermal exchanger and, in particular, to prevent etching the portions located above the thermal vias as in step 1040. The second resist layer exposes portions of the thermal exchanger that are on the dielectric layer for etching in step 1318. At step 1318, the exposed portions of the thermal exchanger are at least partially etched to form a patterned upper portion of the thermal exchanger (e.g., to form upper portion 212). The exposed portions may be removed via a full etch, stopping at the dielectric layer surface (e.g., to form upper portions 402). The patterned thermal exchanger may enhance fluid cooling efficiency by improving the heat exchange between the structure and fluid coolant. In some embodiments, at step 1320, a protective layer is disposed over the patterned thermal exchanger to prevent damaging effects due to fluid coolant. At step 1322, the thermal exchanger is enclosed in a fluid chamber (e.g., by coupling a housing to the thermal exchanger) to form a fluid-cooled microelectronic assembly. The fluid chamber's housing may be attached to a surface of the thermal exchanger, the substrate, and/or a second substrate (e.g., as shown in structures 100, 500, 520, 540, 600).

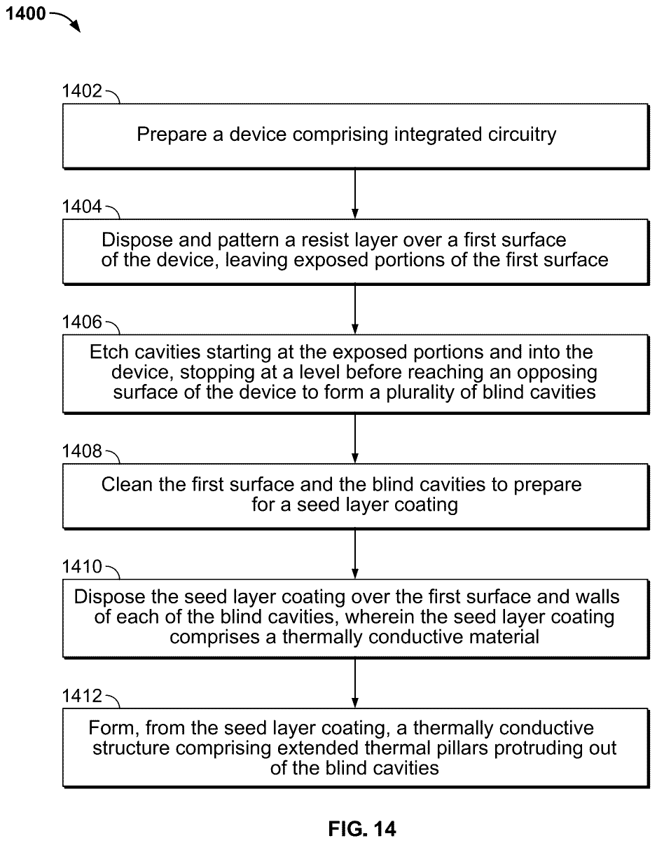

FIG. 14 is a flowchart of a process 1400 for forming a thermal exchanger including extended thermal vias for fluid cooling, in accordance with some embodiments of the disclosure. At step 1402, a device comprising integrated circuitry is prepared, for example, by planarizing and cleaning the front side and back side of the device. At step 1404, a resist layer is disposed and patterned over a first side of the device. Patterning the resist layer leaves portions of the device exposed for a selective etching process. At step 1406, cavities are etched into the device at the exposed portions, starting from the first side. The cavities extend into the device and stop at a level before reaching the opposing side of the device, forming a plurality of blind cavities. At step 1408, sides of the device and blind cavities are cleaned in preparation for a conformal coating such as a seed layer coating. The resist layer may be removed (e.g., to form structures 400, 410, 420) or left on the device (e.g., as shown in FIG. 12). At step 1410, the coating is conformally disposed over the device and walls of the blind cavities. The coating comprises a thermally conductive material. The coating may be used to form a conformal thermally conductive structure (e.g., structures 220, 230). At step 1412, extended thermal vias are formed from the coating by overfilling the blind cavities (e.g., structures 400, 410, 420). The extended thermal vias protrude outside the cavities to a level above the dielectric layer or above the resist layer such as in the structure of step 1220.

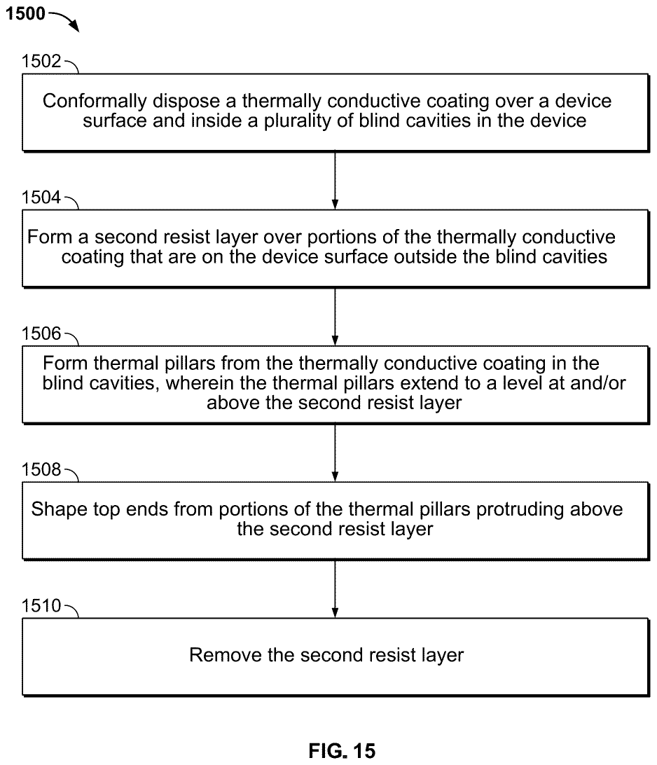

FIG. 15 is a flowchart of a process 1500 for forming a conformal, shaped thermal exchanger for fluid cooling, in accordance with some embodiments of the disclosure. A device including one or more blind cavities may be prepared (e.g., using processes 1300, 1400). At step 1502, a thermally conductive material is conformally disposed over a side of the device and inside the blind cavities to form a thermal coating. At 1504, a second resist layer is formed over portions of the thermal coating that are on the device surface and outside the cavities. At 1506, thermal vias are formed from the thermal coating inside the blind cavities. The thermal vias extend to at least a level above the device surface. Preferably, the thermal vias reach a level at or above the second resist layer. At 1508, the upper portions of the thermal vias are shaped. For example, the thermal pillar portions protruding above the second resist layer may be rounded, smoothed, roughened, etc., such as in the structure of step 1220. At 1510, the second resist layer is removed, leaving a thermal exchanger with extended thermal vias.

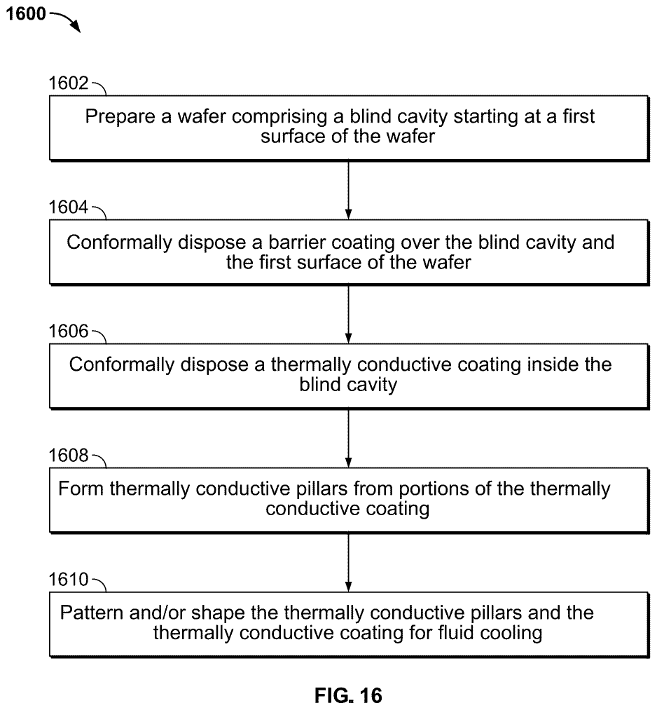

FIG. 16 is a flowchart of a process 1600 for forming a conformal, shaped thermal exchanger within a large cavity for fluid cooling, in accordance with some embodiments of the disclosure. Process 1600 may be involved in forming, for example, structures 810, 820. At step 1602, a wafer is prepared. The wafer includes one blind cavity such as wide cavity 804. The blind cavity starts at a first side of the wafer. The blind cavity extends into the wafer and stops at a level before reaching the opposing side of the wafer. At 1604, a barrier coating is conformally disposed over the blind cavity and the first side of the wafer. At 1606, a thermal coating is conformally disposed over the barrier coating inside the blind cavity. The thermal coating comprises a thermally conductive material. The barrier coating preferably has minimal or no detrimental effect on the thermal conduction between the wafer and the thermal coating. For example, the barrier coating may comprise a thin dielectric coating and/or a diffusion barrier. In some embodiments, the barrier coating enhances the thermal path between the wafer and the thermal coating. For example, the barrier coating may comprise a material having a higher thermal conductivity than material of the wafer. At 1608, thermally conductive vias are formed from portions of the thermal coating. For example, the thermal coating may be used as a seed layer for electroless plating. In some embodiments, the thermally conductive vias may comprise a material that has a higher thermal conductivity than the thermal coating. For example, the vias may comprise carbon-based nanotubes. At 1610, the thermal coating and vias are patterned and/or shaped for fluid cooling.

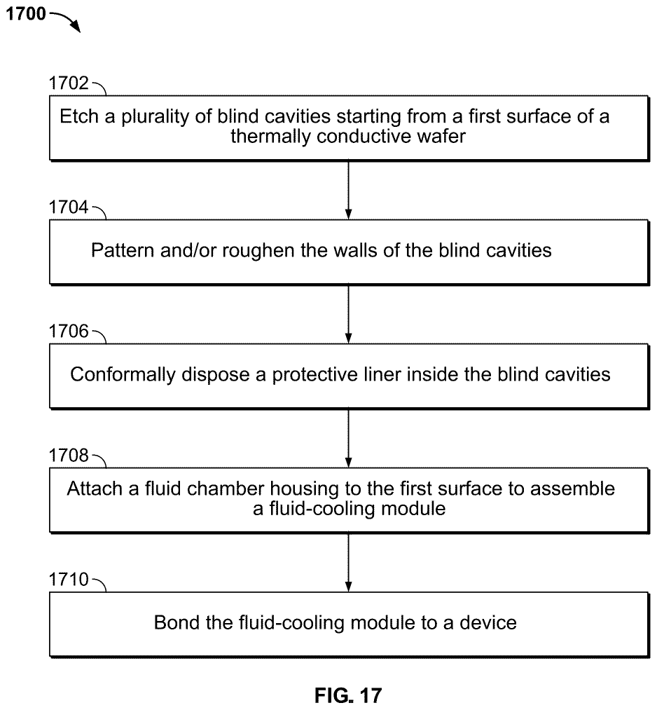

FIG. 17 is a flowchart of a process 1700 for forming a fluid cooling module including a conformal thermal exchanger within patterned and/or textured cavities, in accordance with some embodiments of the disclosure. Process 1700 may be involved in forming, for example, structures 900, 920. A wafer comprising a thermally conductive material is provided. The wafer may comprise integrated circuitry, for example, in a device region near to the front side of the wafer. At 1702, the wafer is etched to form a plurality of blind cavities. Forming the blind cavity may include forming a cavity topography to improve fluid cooling efficiency (e.g., mounds 906). At 1704, surfaces and/or walls of the blind cavity are patterned, for example, by roughening the surfaces to form a textured side. At 1706, a protective liner is conformally disposed over the textured side of the blind cavity. For example, a thin dielectric coating may be disposed to include the texture of the blind cavity surface. At 1708, a fluid chamber housing is attached to a side of the wafer such as the first side outside the blind cavity or the sides of the wafer. Attaching the fluid chamber housing to the wafer assembles a fluid-cooling module. At 1710, the fluid cooling module is bonded to a device using the front side of the wafer such as in structure 920. For example, the front side of the wafer may be hybrid bonded to the device.

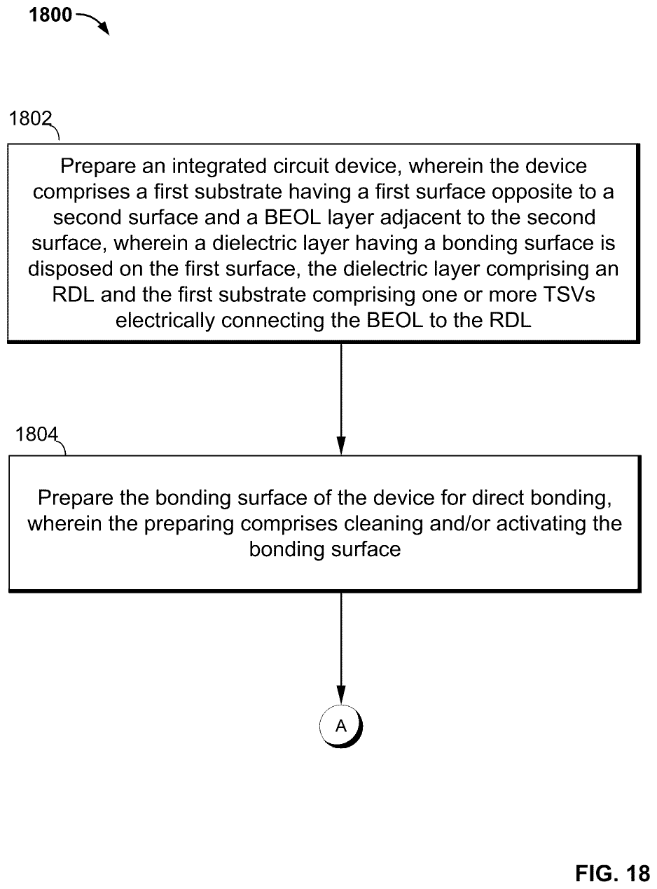

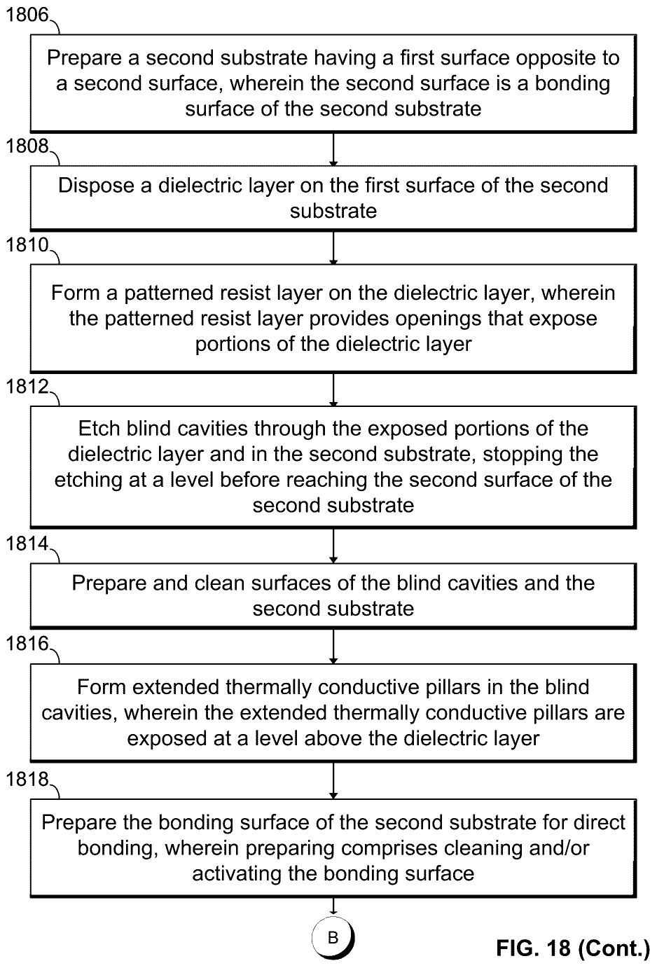

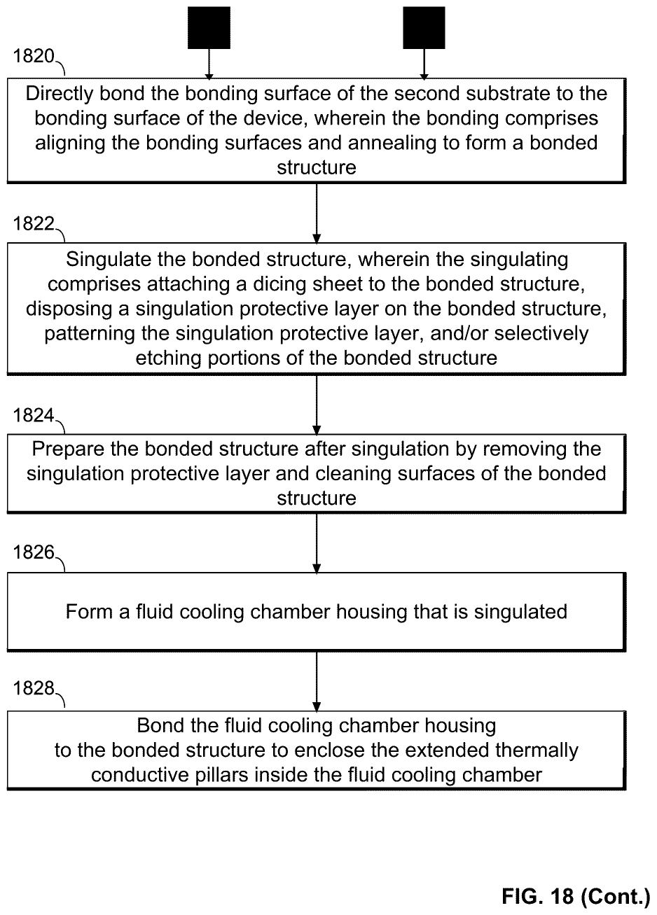

FIG. 18 is a flowchart of a process 1800 for forming a thermal exchanger including extended thermal vias for fluid cooling, in accordance with some embodiments of the disclosure. Process 1800 may be involved in forming, for example, structures 500, 520, 540, and/or 920. At step 1802, a device comprising integrated circuitry is prepared. The device may comprise a first substrate having first and second opposing sides (e.g., front side and back side surfaces). For example, the substrate of the device may be a thinned substrate having a thickness less than 500 μm. In some embodiments, the first side may be the back side of the first substrate, and the second side of the substrate may be adjacent to a BEOL layer of the device. The first side may be coated with a dielectric layer providing a smooth surface suitable for bonding. For example, the dielectric layer may be planarized. In some embodiments, the dielectric layer may comprise a redistribution layer (RDL), and the first substrate may comprise one or more thru-substrate vias (TSVs) electrically connecting the BEOL layer adjacent to the second side to the RDL of the dielectric layer on the first side. At step 1804, a bonding surface of the device (e.g., the dielectric layer surface) is prepared for direct bonding. For example, the preparation may include cleaning and/or activating the bonding surface and/or other suitable sides. After step 1804, process 1800 may continue to step 1820. A process involving steps 1802 and 1804 may be performed separately (e.g., before, after, or in parallel) from steps 1806-1818 before continuing to step 1820 as described in the following paragraphs.

At step 1806, a second substrate having a first side opposite to a second side is prepared. One or both of the substrate surfaces may comprise a bonding surface. As an illustrative example, the second side may comprise a bonding surface that is planarized and smooth. At 1808, a dielectric layer is disposed over the first side of the second substrate. In some embodiments, the dielectric layer disposed over the first side comprises and/or forms a surface suitable for bonding. At 1810, a patterned resist layer is formed on the dielectric layer disposed over the first side. The resist layer is suitably patterned for forming a thermally conductive structure. For example, the resist layer may provide gaps or openings that expose selected portions of the dielectric layer, for example, to support a selective etching process. At step 1812, one or more cavities are etched through the exposed portions of the dielectric layer and extending into the second substrate. The etch is stopped at a level before reaching the second side of the second substrate, forming one or more blind cavities.

At step 1814, sides of the second substrate and the blind cavities are prepared and cleaned for forming a thermally conductive structure comprising thermally conductive vias. At step 1816, extended thermally conductive vias are formed in the blind cavities. The extended thermally conductive vias fill the blind cavities and may be exposed at a level above the dielectric layer. At step 1818, the second side of the second substrate is prepared for direct bonding. For example, the preparation may include cleaning and/or activating the second side and/or other suitable bonding surfaces. A process involving steps 1806-1818 may be performed separately (e.g., before, after, or in parallel) before continuing to step 1820.

Process 1800 continues from steps 1804 and 1818. At step 1820, the bonding surface of the second substrate is directly bonded to the bonding surface of the device (e.g., the dielectric layer on the first side of the first substrate). In some embodiments, directly bonding the bonding surfaces may comprise aligning the alignment marks on the respective substrates before finalizing the direct bonding process to form a completed bond (e.g., prior to annealing). At step 1822, the bonded substrates are annealed at a suitable temperature and annealing duration, finalizing the direct bonding process to form a strongly bonded pair or a bonded structure. In some aspects, the completed bond may be sufficiently strong to be referred as a permanently bonded pair. The bonded structure comprises the device bonded to the second substrate and the thermally conductive structure comprising the extended thermally conductive vias in the blind cavities of the second substrate. At step 1822, in some embodiments, the bonded structure is singulated. For example, the bonded structure may be attached to a dicing sheet for singulation. Singulating the bonded structure may further comprise coating a side of the bonded structure with a suitable protective layer prior to the singulation. In some embodiments, the protective layer is patterned to support selective etching of portions of the bonded structure.

At step 1824, the bonded structure is cleaned to remove unwanted materials such as debris that may interfere with the thermal pathway. For example, cleaning the bonded structure after singulation may comprise removing the singulation protective layer. At step 1826, a fluid cooling chamber housing (e.g., housing 510 of fluid chamber 502) is formed and/or assembled for attaching to the bonded structure. For example, the fluid cooling chamber housing may be prepared at a different manufacturing site. In some embodiments, the fluid cooling chamber housing is a singulated chamber housing. At 1828, the fluid cooling chamber housing is coupled to the bonded structure. For example, a singulated bonded structure may be selected from the dicing frame. The fluid cooling chamber housing may be bonded to the first side of the second substrate to enclose the extended thermal vias inside the fluid cooling chamber. Such a structure may be depicted by structures 500, 520, 540 shown in FIG. 5. For example, referring to FIG. 5, the layer 106 may be a device or substrate directly bonded to the device 102. Extended thermal vias such as thermal structures 504, 524, or 556 are disposed on a second side of the device 102 opposite to the side bonded to layer 106. The extended thermal vias may be exposed to the fluid cooling chamber interior (as shown in chambers 502, 522). The fluid cooling chamber housing may be coupled to the second side of the device 102 via a bonding layer (e.g., layer 508, 526). For example, the thermal vias may be occluded in the fluid cooling chamber. In some embodiments, two or more substrates may be directly bonded together to form the layer 106. The directly bonded substrates may be directly bonded to the device 102. In some embodiments, the layer 106 and/or the device 102 comprise an interposer. The interposer may comprise bonded dies (e.g., with varying dimensions) on a side of the interposer. The side of the interposer may be bonded to the device 102 comprising the thermal vias via the bonded dies.

The embodiments and figures discussed herein are intended to be illustrative and not limiting to the present disclosure. One skilled in the art would appreciate that individual aspects of the structures and methods as discussed may be omitted, modified, combined, and/or rearranged without departing from the scope of the invention. Only the claims that follow are meant to set bounds as to what the present invention includes.

1. (canceled)

2. A method for fluid cooling a semiconductor device having a first side and a second side opposite to the first side, the method comprising:
forming a thermal exchanger on the semiconductor device that starts at a first level above the first side, comprising:
etching cavities starting at the first side and in the semiconductor device, the cavities stopping at a second level before reaching the second side;
depositing a thermally conductive layer in the cavities, the thermally conductive layer starting at the first level; and
forming, from the thermally conductive layer, the thermal exchanger comprising (i) a plurality of thermal vias disposed in the cavities and ending at the second level and (ii) an upper portion of the thermally conductive layer to form a plurality of protrusions above the first side, the plurality of protrusions ending at the first level; and
coupling a housing to the thermal exchanger to form a fluid chamber having a chamber volume disposed between the thermal exchanger and the housing, wherein the upper portion of the thermal exchanger is exposed to and faces the chamber volume.

3. The method of claim 2, further comprising:
coupling, via the housing, the chamber volume to at least one fluid inlet line and at least one fluid outlet line of a fluid coolant system.

4. The method of claim 2, wherein the semiconductor device comprises a dielectric layer disposed on the first side and the plurality of thermal vias are disposed through the dielectric layer.

5. The method of claim 2, further comprising forming a redistribution layer on the second side of the semiconductor device.

6. The method of claim 2, wherein etching the cavities comprises:
disposing a resist layer pattern over the first side, leaving exposed portions of the first side; and
etching the first side and the semiconductor device at the exposed portions to form the cavities.

7. The method of claim 2, further comprising:
forming a corrosion resistant protective layer over the upper portion of the thermal exchanger.

8. The method of claim 2, wherein depositing the thermally conductive layer comprises depositing a conformal seed layer.

9. The method of claim 2, further comprising depositing a diffusion barrier in the cavities prior to depositing the thermally conductive layer.

10. The method of claim 2, wherein depositing the thermally conductive layer comprises:
depositing a first portion of the thermally conductive layer in the cavities using a first electrochemical process; and
depositing a second portion of the thermally conductive layer in the cavities using a second electrochemical process.

11. The method of claim 2, wherein the thermally conductive layer comprises first and second thermally conductive materials, and wherein depositing the thermally conductive layer comprises:
conformally depositing the first thermally conductive material to line the cavities; and
depositing an overburden of the second thermally conductive material.

12. The method of claim 11, wherein the second thermally conductive material has a thermal conductivity greater than the first thermally conductive material.

13. The method of claim 12, wherein the second thermally conductive material comprises at least one of diamond, metal-diamond composite, diamond-like carbon, and carbon nanotubes.

14. The method of claim 2, wherein, prior to coupling the housing to the thermal exchanger, the method further comprises:
singulating the device and thermal exchanger from a substrate comprising a plurality of devices and thermal exchangers; and
preparing the second side for direct dielectric bonding or hybrid bonding.

15. The method of claim 2, wherein coupling the housing to the thermal exchanger comprises directly bonding the housing to the thermal exchanger.

16. The method of claim 2, wherein coupling the housing to the thermal exchanger comprises hybrid bonding the housing to the thermal exchanger.

17. The method of claim 2, further comprising forming fluid cavities in the plurality of thermal vias.

18. The method of claim 2, further comprising:
forming a grounding via starting from the first and stopping at the second side.

19. The method of claim 2, wherein the plurality of thermal vias is arranged to correspond to differences in heat generated by different regions of the semiconductor device.

20. The method of claim 2, wherein inwardly facing sides of the housing form obtuse angles.

21. The method of claim 2, wherein inwardly facing sides of the housing form concave surfaces.

22. The method of claim 2, wherein the semiconductor device comprises a three-dimensional stacked integrated circuit.
